(19) United States
(12) Patent Application Publication
(10) Pub. No.: US 2015/0214103 A1
(43) Pub. Date: Jul. 30, 2015

(54) SEMICONDUCTOR DEVICE AND METHOD OF MANUFACTURING THE SAME

(71) Applicant: Kabushiki Kaisha Toshiba, Minato-ku (JP)

(72) Inventor: Yuya MATSUDA, Mie-gun (JP)

(73) Assignee: Kabushiki Kaisha Toshiba, Minato-ku (JP)

(21) Appl. No.: 14/549,789

(22) Filed: Nov. 21, 2014

(30) Foreign Application Priority Data
Jan. 24, 2014 (JP) 2014-011307

(51) Int. Cl. H01L 21/768; H01L 27/115

(52) U.S. Cl. CPC H01L 21/76877; H01L 27/115

(57) ABSTRACT

A semiconductor device includes a stack of conductive films, the stack of conductive films having a stairway portion located at an end portion thereof; an insulating layer disposed above the stack of conductive films; contact electrodes having different depths extending from an upper surface of the insulating layer to establish connection with upper surfaces of the conductive films in the stairway portion, the contact electrodes having different depths being arranged into at least a first contact group and a second contact group; an adjustment film disposed in the insulating layer; the contact electrodes in the second contact group extending through the adjustment film, a contact electrode having the smallest depth in the first contact group being deeper than a contact electrode having the greatest depth in the second contact group.

### CROSS-REFERENCE TO RELATED APPLICATION(S)

This application is based upon and claims the benefit of priority from Japanese Patent Application No. 2014-011307, filed on, Jan. 24, 2014 the entire contents of which are incorporated herein by reference.

### FIELD

Embodiments disclosed herein generally relate to a semiconductor device and a method of manufacturing the same.

### BACKGROUND

When contacts, connecting to the upper surfaces of conductive films stacked in a stairway configuration, are formed simultaneously, the depths of the contact openings vary significantly between the lower layer films and the upper layer films of the stack. Thus, the stopper film disposed below the bottom portion of a relatively shallow contact becomes excessively etched, so that the etching progresses through the stopper film and possibly electrically shorts the underlying conductive film.

### BRIEF DESCRIPTION OF THE DRAWINGS

FIG. 1 is one example of a perspective view schematically illustrating the configuration of a memory-cell portion of a nonvolatile semiconductor storage device of the embodiments.

FIG. 2A pertains to the first embodiment and is one schematic example of a vertical cross-sectional view of structures of a nonvolatile semiconductor storage device (a schematic vertical cross-sectional view taken along line A-A of FIG. 1).

FIG. 2B is one example of a vertical cross-sectional view of a wire connecting portion at the end of a memory portion.

FIG. 3 is one example of a vertical cross sectional view schematically illustrating a stairway configuration formed by a conductive film disposed in the wire connecting portion.

FIG. 4 pertains to the first embodiment and is one example of a vertical cross-sectional view illustrating the manufacturing process flow.

FIG. 5 pertains to the first embodiment and is one example of a vertical cross-sectional view illustrating the manufacturing process flow.

FIG. 6 pertains to the first embodiment and is one example of a vertical cross-sectional view illustrating the manufacturing process flow.

FIG. 7 pertains to the first embodiment and is one example of a vertical cross-sectional view illustrating the manufacturing process flow.

FIG. 8 pertains to the first embodiment and is one example of a vertical cross-sectional view illustrating the manufacturing process flow.

FIG. 9 pertains to the first embodiment and is one example of a vertical cross-sectional view schematically illustrating a different aspect of the nonvolatile semiconductor storage device (a schematic vertical cross-sectional view taken along line A-A of FIG. 1).

FIG. 10 pertains to a second embodiment and is one example of a vertical cross-sectional view illustrating the manufacturing process flow.

FIG. 11 pertains to the second embodiment and is one example of a vertical cross-sectional view illustrating the manufacturing process flow.

FIG. 12 pertains to the second embodiment and is one example of a vertical cross-sectional view illustrating the manufacturing process flow.

FIG. 13 pertains to the second embodiment and is one example of a vertical cross-sectional view illustrating the manufacturing process flow.

FIG. 14 pertains to the second embodiment and is one example of a vertical cross-sectional view illustrating the manufacturing process flow.

FIG. 15 pertains to the second embodiment and is one example of a vertical cross-sectional view illustrating the manufacturing process flow.

FIG. 16 pertains to the second embodiment and is one example of a vertical cross-sectional view illustrating the manufacturing process flow.

FIG. 17 pertains to a third embodiment and is one example of a vertical cross sectional view schematically illustrating a stairway configuration formed by a conductive film disposed in a wire connecting portion.

FIG. 18 pertains to a fourth embodiment and is one example of a vertical cross sectional view schematically illustrating a stairway configuration formed by a conductive film disposed in a wire connecting portion.

FIG. 19 illustrates one example of how the stairway configuration of adjustment film is formed.

FIG. 20 illustrates one example of how the stairway configuration of adjustment film is formed.

FIG. 21 illustrates one example of how the stairway configuration of adjustment film is formed.

FIG. 22 illustrates one example of how the stairway configuration of adjustment film is formed.

FIG. 23 illustrates one example of how the stairway configuration of adjustment film is formed.

### DETAILED DESCRIPTION

An embodiment of a semiconductor device includes a stack of conductive films, the stack of conductive films having a stairway portion located at an end portion thereof; an insulating layer disposed above the stack of conductive films; contact electrodes having different depths extending from an upper surface of the insulating layer to establish connection with upper surfaces of the conductive films in the stairway portion, the contact electrodes having different depths being arranged into at least a first contact group and a second contact group; an adjustment film disposed in the insulating layer; the contact electrodes in the second contact group extending through the adjustment film, a contact electrode having the smallest depth in the first contact group being deeper than a contact electrode having the greatest depth in the second contact group.

An embodiment of a method of manufacturing a semiconductor device includes forming a stack of conductive films and interelectrode insulating films above a semiconductor substrate; forming a stairway portion by processing the conductive films and the interelectrode insulating films at an end portion of the stack of films; forming an insulating film including an adjustment film above the stack of films including the stairway portion; forming contact holes having different depths so as to extend from an upper surface of the insulating film and establish connection with upper surfaces of the conductive films and so that the contact holes are arranged into contact groups depending upon depths of the contact holes, contact holes belonging to the deepest contact group among the contact groups do not extend through the adjustment film, and contact holes belonging to other one or more contact groups extend through the adjustment film.

### Embodiments

Embodiments are described hereinafter with reference to the drawings. The drawings are schematic and thus, are not necessarily consistent with the actual correlation of thickness to planar dimensions and the actual thickness ratios between each of the layers. Thus, the same portion may be illustrated in different dimensions or ratios in different figures. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. In the drawings referred to in the following description, elements that are identical or similar to those already illustrated or described are identified with identical or similar reference symbols and may not be re-described. Further, in the following description, XYZ orthogonal coordinate system is used for convenience of explanation. In the coordinate system, the X direction and the Y direction each indicates a direction parallel to the surface of a semiconductor substrate and crosses with one another. The direction crossing with both the X and the Y direction is referred to as the Z direction.

### First Embodiment

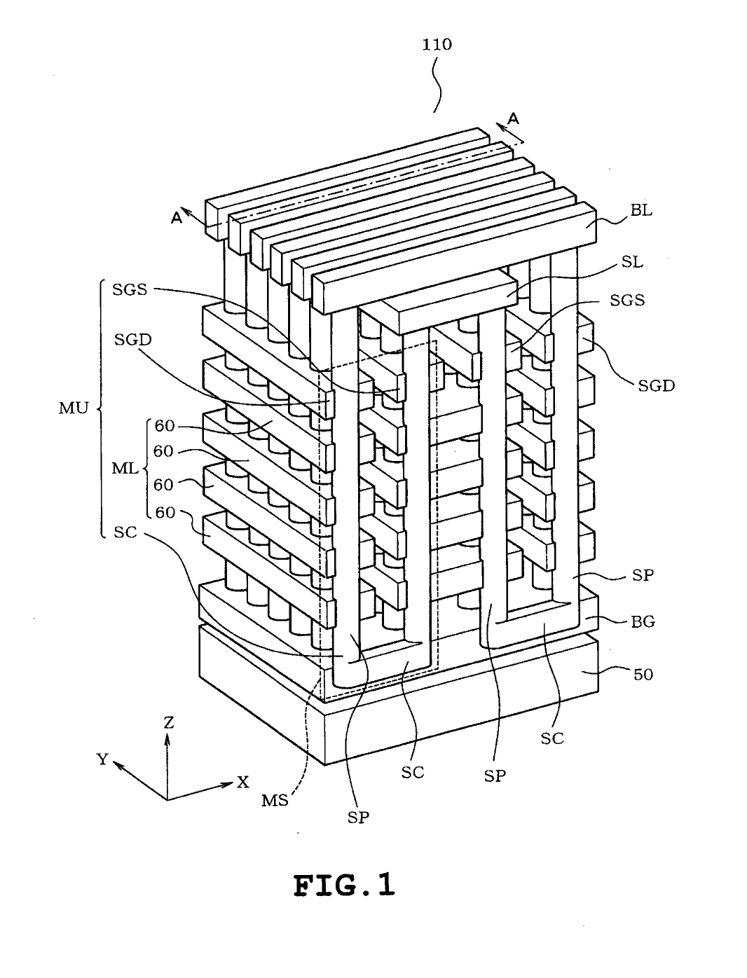

A first embodiment will be described hereinafter with references to FIG. 1 to FIG. 9.

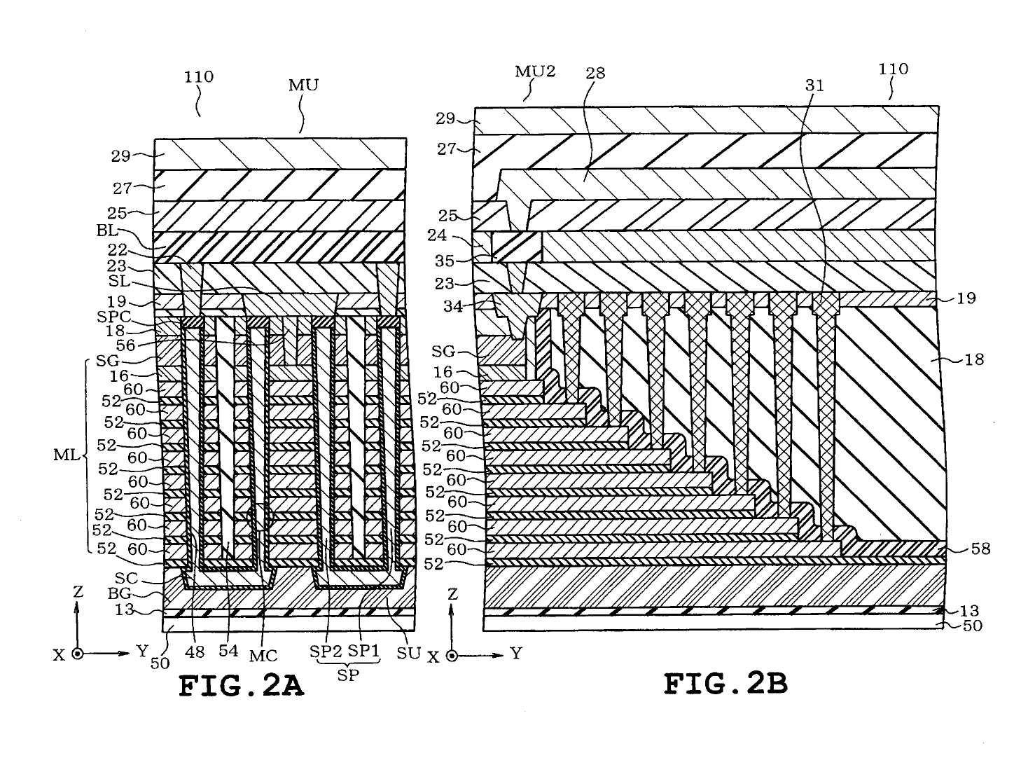

One example of a stacked-type nonvolatile semiconductor storage device is illustrated in FIG. 1, FIG. 2A, and FIG. 2B as one example of a semiconductor device. More specifically, the example of the stacked-type nonvolatile semiconductor storage device is configured as a NAND-type nonvolatile semiconductor storage device comprising a semiconductor substrate, conductive films, pillar electrodes, and electron trap films. The pillar electrodes are formed into pairs such that a couple of pillar electrodes are interconnected at their lower portions. Each pair of pillar electrodes is disposed orthogonal to the semiconductor substrate so as to extend through a stack of conductive films. An electron trap film is disposed between the pillar electrode and the conductive film, thereby forming a storage element.

FIG. 1 is one example of a perspective view schematically illustrating the structure of a memory-cell portion of nonvolatile semiconductor storage device 110. FIG. 1 illustrates the conductive portions for convenience of explanation and does not illustrate the insulating portions.

FIG. 2A is one example of a vertical cross-sectional view schematically illustrating the structure of nonvolatile semiconductor storage device 110 of the first embodiment taken along line A-A of FIG. 1. FIG. 1 and FIG. 2A both illustrate one example of a structure of memory portion MU.

FIG. 1 and FIG. 2A illustrate memory portion MU comprising storage elements arranged in a three-dimensional matrix provided in a memory-cell portion. Memory portion MU is disposed above insulating film 13 provided above semiconductor substrate 50. Back gate BG is disposed above insulating film 13. Memory portion MU has conductive films 60. Each of conductive films 60 are shaped like a belt spreading planarly (two-dimensionally) in the direction running along the surface of semiconductor substrate 50 (the direction of XY plane). Conductive films 60 are stacked into multiple layers. Conductive films 60 serve as word lines of memory cells MC of nonvolatile semiconductor storage device 110. Interelectrode insulating film 52 is disposed between the stack of conductive films 60. Select gate electrode SG is disposed above conductive film 60 in the uppermost layer of the stack. Conductive films 60 and select gate electrode SG form stack structure ML. Examples of select gate electrode SG include drain-side select gate electrode SGD and source-side select gate electrode SGS for selecting memory strings.

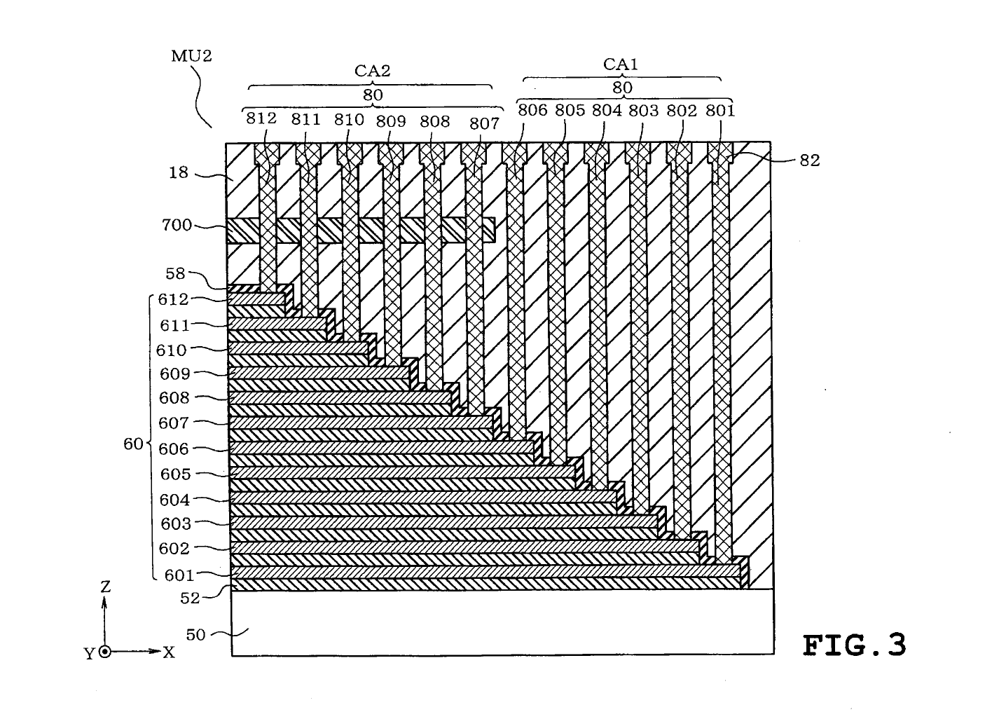

Though eight layers of conductive films 60 are illustrated in FIG. 2A and FIG. 2B, any number of conductive films 60 may be stacked in stack structure ML. FIG. 1 illustrates four layers for example for good visibility. The later described FIG. 3 to FIG. 9 illustrate examples of 12 layers of conductive films 60 for convenience of explanation.

Conductor pillars SP extend in the direction orthogonal to semiconductor substrate 50 (Z direction) and extend through stack structure ML. Two conductor pillars SP form a pair (illustrated as SP1 and SP2 in the figures) for example. The pair of conductor pillars SP (SP1 and SP2) are interconnected at their lower portions through connecting portion SC and thus are collectively shaped like a letter U. Back gate BG is disposed so as to surround connecting portion SC via insulating film. The conductive state of connecting portion SC is controlled by applying voltages to connecting portion SC.

Conductor pillar SP may be formed by for example, filling a hole extending in the Z direction through stack structure ML and select gate electrode with a semiconductor film (such as amorphous silicon). Conductor pillar SP may be formed in the shape of a cylinder (circular cylinder) or column (circular column) extending in the Z direction. The inner side of the semiconductor film inside conductor pillar SP may be hollow or may be filled with an insulating layer.

A block film, a charge film, and a tunnel film for example may be provided between the semiconductor film and conductive film 60 inside conductor pillar SP to serve as memory portion MU for storing information. The block film may be formed of a silicon oxide film for example. The charge film may be formed of a silicon nitride film for example. Tunnel film may be formed of a silicon oxide film for example.

In memory cell MC (memory-cell transistor), conductive film 60 serves as a gate electrode, conductor pillar SP serves as a channel portion, the block film, the charge film, and the tunnel film serve as a gate insulating film and charge storing layer (storage layer 48). The memory-cell transistor is arranged in a three-dimensional matrix. Each of memory-cell transistors serve as memory cell MC for storing information (data) by accumulating charge in storage layer 48.

One of conductor pillars SP (SP1) forming the pair of conductor pillars SP is connected to bit line BL and remaining other (SP2) of the pair is connected to source line SL at a connection site located above memory portion MU. As a result, the paired conductor pillars SP (SP1 and SP2) are connected so as to extend continuously from bit line BL to source line SL to form a single memory string MS.

Conductive films 60 and select gates SG are divided in the Y direction by dividing layer 54 extending in the X direction between the paired conductive layers SP (between SP1 and SP2) as viewed in the figures. Select gates SG are divided in the Y direction by dividing layer 56 extending in the X direction between adjacent conductor pillars SP2.

Interlayer insulating film 18 is disposed above select gate electrodes SG. Pillar contact portions SPC are disposed above conductor pillars SP, and source lines SL and contact electrodes 22 are further disposed above pillar contact portions SPC. Source line SL is surrounded by interlayer insulating film 19. Interlayer insulating film 23 is disposed above source line SL and bit line BL is further disposed above interlayer insulating film 23. Bit line BL is formed for example of a line-and-space pattern extending in the Y-axis direction. Interlayer insulating film 25, interlayer insulating film 27 and passivation film 29 are disposed above bit line BL.

FIG. 2B illustrates one example of a cross-sectional structure of wire connecting portion MU2 located at the end of memory portion MU. Word line WL (conductive film 60) is connected to a peripheral circuit not illustrated at wire connecting portion MU2. In wire connecting portion MU2, the end portions of conductive films 60 are laid out like a stairway such that conductive films 60 serve as steps of the stairway. Contact electrodes 31 are connected to the upper surfaces of the steps, that is, the upper surfaces of the end portions of the conductive films 60. Thus, contact electrodes 31 being connected to conductive films 60 (word lines) are capable of applying predetermined voltages to conductive films 60.

Contact electrodes 31 are connected to the peripheral circuit not illustrated. Peripheral circuit is provided around memory portion MU and is responsible for, among other operations, writing information into/reading information out of memory cell MC. Select gate electrode SG is connected to memory portion contact wire 34. The side surfaces of memory portion contact electrode 31 and memory portion contact wire 34 are covered with interlayer insulating film 18. In FIG. 2B, contact electrodes 31 are illustrated so as to be disposed next to one another in the same cross section. Contact electrodes 31 may be displaced one after another in the back and forth direction (Y direction) as viewed in the figures.

As illustrated, stopper film 58, interlayer insulating film 18, and interlayer insulating film 19 are formed above conductive film 60 laid out like a stairway. Each of contact electrodes 31 extend through these films and connect to the surface of the associated conductive film 60. Select gate electrode SG is connected for example to a dedicated wire 35 by memory portion contact wire 34. Interlayer insulating film 25 is provided above wire 35 and metal wire 28 connected to wire 35 is provided above interlayer insulating film 25. The side surfaces of contact electrode 31 of the memory portion and contact wire 34 of the memory portion are covered by interlayer insulating film 18.

As described above, conductor pillars SP (SP1 and SP2) are connected to bit line BL or source line SL. Select gate electrode SG (SGD and SGS) provided for each of conductor pillars SP allows writing/reading of the desired data to/from a given memory cell MC of a given conductor pillar SP.

Next, the structures of the first embodiment will be described in detail with reference to FIG. 3. FIG. 3 is one example of a vertical cross-sectional view schematically illustrating the stairway structure formed by conductive film 60 in wire connecting portion MU2 illustrated in FIG. 2B. In FIG. 3 to FIG. 9, twelve layers of conductive films 60 are illustrated for convenience of explanation. Though any number of layers of conductive films 60 may be provided, multiples of 8 are common or frequently employed number of layers. Dummy layers may be provided for example in addition to the above described number of layers.

In FIG. 3, twelve layers of conductive films 60 are provided as described above. Conductive film 60 in the lowermost layer is represented as conductive film 601, and subsequent layers are represented in sequence as conductive film 602, conductive film 603, and so forth, and conductive film 60 in the uppermost layer is represented as conductive film 612. Interelectrode insulating film 52 is provided between conductive films 60 for insulating conductive films 60. Conductive film 60 is formed of for example an amorphous silicon. The amorphous silicon may or may not be doped with impurities. Impurities such as phosphorous, boron, or the like are used when doping the amorphous silicon. A silicon oxide film may be used for example as interelectrode insulating film 52.

Stopper film 58 is formed above the upper surfaces of conductive films 60 (601 to 612) arranged like a stairway. A silicon nitride film may be used for example as stopper film 58. Interlayer insulating film 18 is provided above stopper film 58. A silicon oxide film may be used for example as interlayer insulating film 18. Adjustment film (etching adjustment film) 700 is provided inside interlayer insulating film 18. A silicon nitride film may be used for example as adjustment film 700.

Contact electrodes 80 (801 to 812) are formed in interlayer insulating film 18. Each of contact electrodes 80 (801 to 806) extend through interlayer insulating film 18 and stopper film 58 and reach the surfaces of the associated conductive films 601 to 606 from the surface of interlayer insulating film 18. Contact electrodes 807 to 812 extend through interlayer insulating film 18 and stopper film 58 and reach the surfaces of the associated conductive films 607 to 612 from the surface of interlayer insulating film 18. Contact electrode 80 is formed for example by a damascene process. Wire 82 is disposed at the upper portion of contact electrode 80 so as to be formed in one with the contact plug portion.

Contact electrodes 801 to 806 are collectively referred to as contact electrode group CA1 and contact electrodes 807 to 812 are collectively referred to as contact electrode group CA2. Contact electrode group CA1 includes relatively deep contact holes (deep contact group). Contact electrode group CA2 includes relatively shallow contact holes (shallow contact group). The depth of the opening of the contact hole for forming contact electrode 807 being the deepest in contact electrode group CA2 is less than the depth of the opening of the contact hole for forming contact electrode 806 being the shallowest in contact electrode group CA1. In the first embodiment, contact holes or contact electrodes having different depths are arranged in multiple contact (electrode) groups depending upon their depths.

Adjustment film 700 is not formed in regions where contact electrode group CA1 is formed. In contrast, adjustment film 700 is formed in region where contact electrode group CA2 is formed and contact electrodes 807 to 812 extend through adjustment film 700. Because the contact holes of shallow contact group CA2 are formed so as to extend through adjustment film 700, it is possible to relax the difference in the depths of the contacts and inhibit penetration of the underlying layer or the like, originating from the difference in the depths.

Next, a manufacturing method of the first embodiment will be described with reference to FIG. 3 to FIG. 8. FIG. 3 to FIG. 8 are examples of vertical cross-sectional views illustrating the manufacturing process flow of the first embodiment. FIG. 3 to FIG. 8 are vertical cross-sectional views of wire connecting portions MU2 and illustrate the sequence of process steps involved in connecting contact electrodes 80 (801 to 812) to the upper surfaces of conductive films 60 (601 to 612).

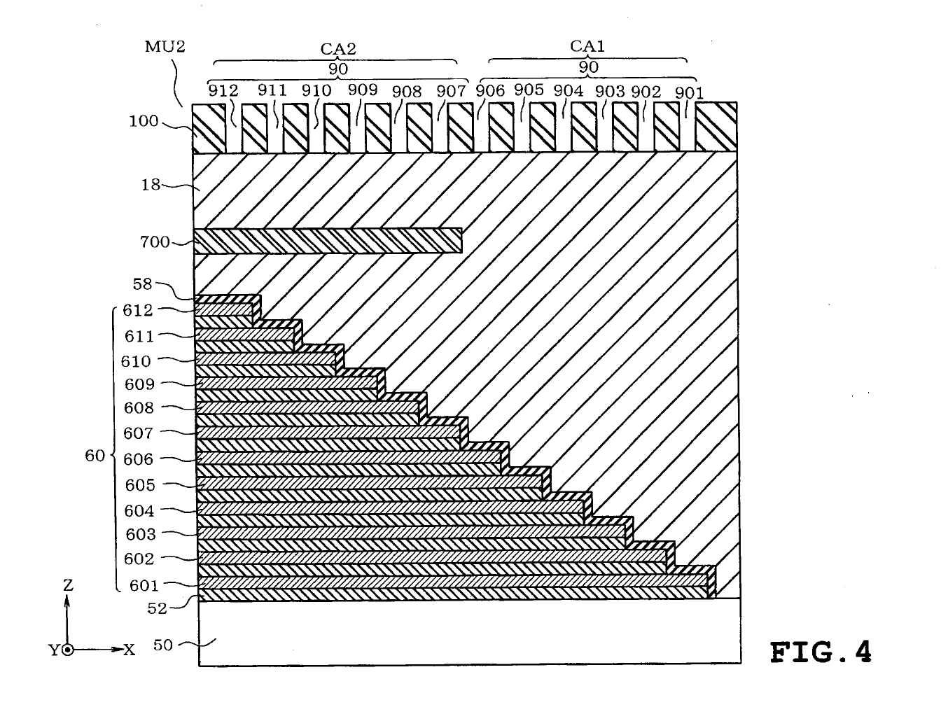

First, as illustrated in FIG. 4, interelectrode insulating film 52 and conductive film 60 are stacked above semiconductor substrate 50 and the structure is processed into a shape of stairway. More specifically, the method described as follows may be employed. A silicon substrate may be used as semiconductor substrate 50. As illustrated in FIG. 2A and FIG. 2B, back gate BG may be formed above semiconductor substrate 50. Semiconductor substrate 50 may be prepared by forming an insulating film above a silicon substrate.

Interelectrode insulating film 52 is formed above semiconductor substrate 50. For example, a silicon oxide film formed by CVD (Chemical Vapor Deposition) may be used as interelectrode insulating film 52. Next, conductive film 60 (601) is formed. Amorphous silicon may be used for example as conductive film 60. Amorphous silicon may be formed for example by CVD.

Next, interelectrode insulating film 52 and conductive film 60 are formed alternately to form a stack of films in which twelve layers of conductive films 60 (601 to 612) and interelectrode insulating films 52 are repeatedly stacked one over the other. Interelectrode insulating film 52 is formed between each of layers of conductive films 601 to 612 so that each of the layers of conductive films 60 are isolated from one another. The first embodiment is described through an example of a stack of films having twelve layers of conductive films 60 and interelectrode insulating films 52 for convenience of explanation. However, the stack of films may have any number of layers and the number of layers need not be limited to twelve.

The following method may be used for example in processing conductive films 60 (601 to 612) into the shape of a stairway. Conductive films 60 (601 to 612) are formed in a stack above semiconductor substrate 50. Then, a resist pattern is formed by lithography and one layer of conductive film 612 and underlying interelectrode insulating film 52 is anisotropically etched by RIE (Reactive Ion Etching). The resist pattern is thereafter receded by slimming. The exposed conductive films 60 (612 and 611) in the uppermost layer and interelectrode insulating films 52 in their underlying layers are etched by RIE. The resist pattern is thereafter receded by slimming. The exposed conductive films 60 (612, 611, and 610) and interelectrode insulating films 52 in their underlying layers are etched by RIE. This is sequentially repeated layer by layer to collectively arrange conductive films 60 into a stairway shape. The resist is slimmed in a layer by layer manner in the above described example. Alternatively, a resist pattern may be formed by lithography for each instance of etching.

Next, stopper film 58 is formed above conductive films 60 processed into the shape of a stairway. A silicon nitride film formed for example by CVD may be used as stopper film 58. Then, interlayer insulating film 18 is formed above stopper film 58 and the surface of interlayer insulating film 18 is planarized by CMP (Chemical Mechanical Polishing). Next, adjustment film 700 is formed. Adjustment film 700 is used to produce a difference in the etch rate from interlayer insulating film 18. Thus, one example of adjustment film 700 may be a silicon nitride film formed by CVD. Thus, a silicon oxide film densified by thermal treatment for example may be used as adjustment film 700 instead of a silicon nitride film. Adjustment film 700 may be obtained by forming an insulating film and patterning the formed insulating film by lithography and RIE. Adjustment film 700 is formed above the portion shaped like a stairway which is formed of conductive films 607 to 612.

Next, interlayer insulating film 18 covering the foregoing structures is formed and the upper surface of interlayer insulating film 18 is planarized by CMP. Next, mask 100 is formed which is used for forming a contact. A resist formed by lithography may be used as mask 100. Further, a carbon film patterned by lithography for example may be used as mask 100 instead of the resist.

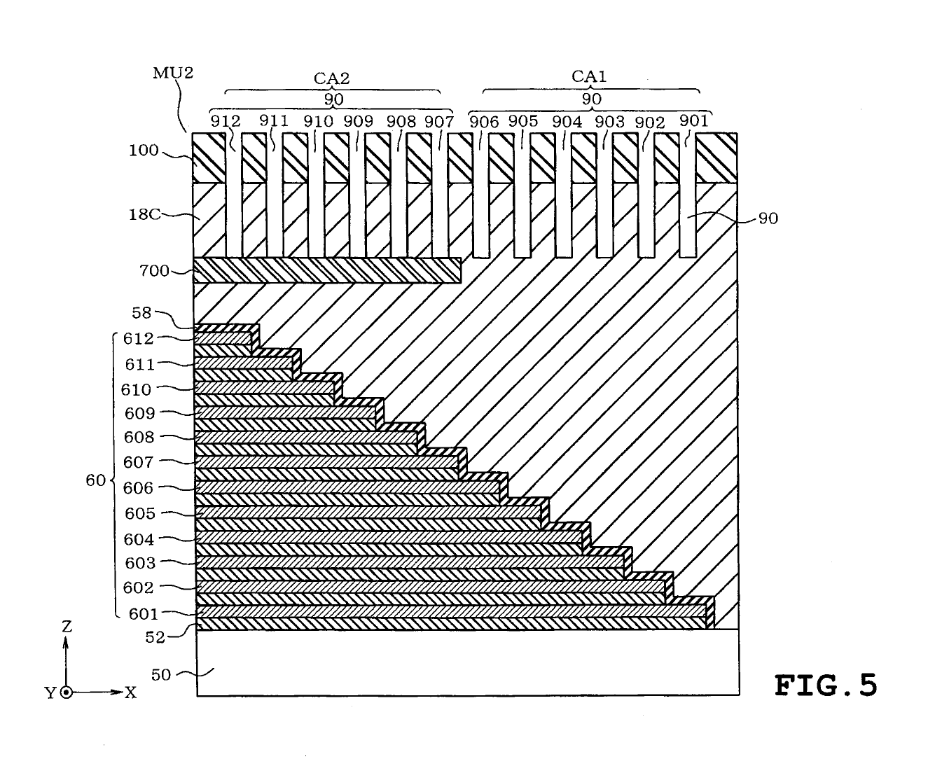

Next, as illustrated in FIG. 5, contact holes 90 (901 to 912) are formed by RIE using mask 100 as an etch mask. FIG. 5 illustrates the ongoing formation of contact holes 90 and more specifically illustrates the state in which the bottom surfaces of contact holes 901 to 912 have reached the upper surface of adjustment film 700. The conditions applied in the etching is configured so that the etch rate silicon nitride film serving as adjustment film 700 is less than the etch rate of silicon oxide film serving as interlayer insulating film 18.

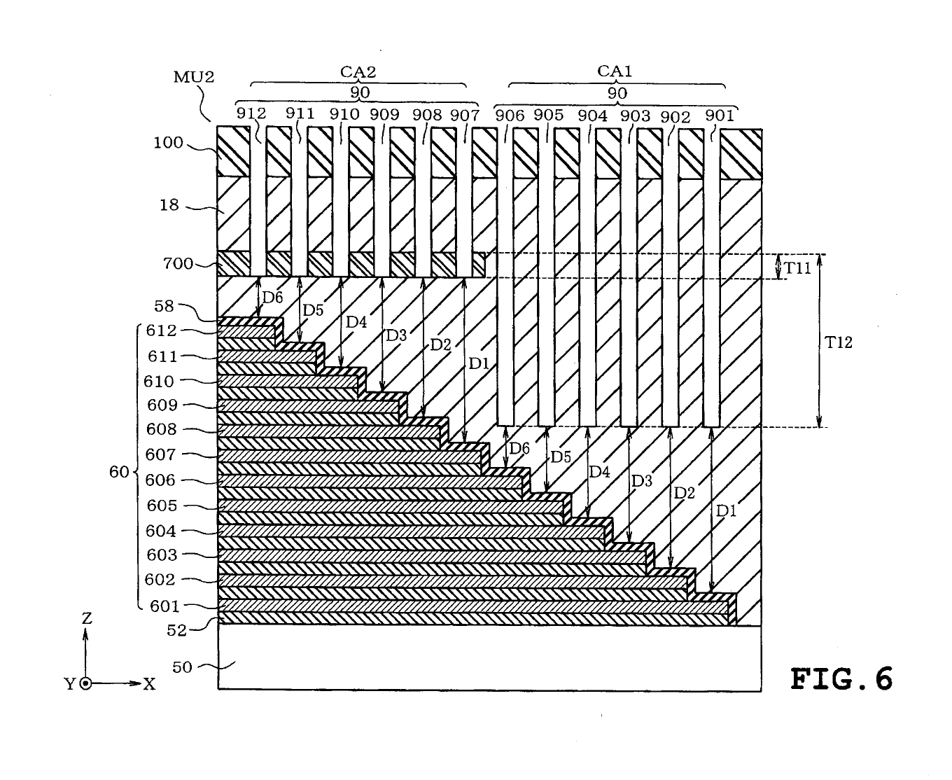

FIG. 6 illustrates the etching progressing to the point where contact holes 907 to 912 have penetrated through adjustment film 700. FIG. 6 further illustrates etching for forming contact holes 901 to 906 progressing further downward within interlayer insulating film 18 as compared to contact holes 907 to 912.

As illustrated in FIG. 6, when the distances between the bottom surfaces of contact holes 901, 902, 903, 904, 905, and 906 to the upper surface of stopper film 58 above conductive films 601, 602, 603, 604, 605, and 606 are represented as D1, D2, D3, D4, D5, and D6, respectively, the distances between the bottom surfaces of contact holes 907, 908, 909, 910, 911, and 912 to the upper surface of stopper film 58 above conductive films 607, 608, 609, 610, 611, and 612 are substantially equal to D1, D2, D3, D4, D5, and D6.

That is, when the contact electrodes are referred to by the group in which they belong, the relation in the distance between the lower portion of contact electrode group CA1 and the upper surfaces of stopper film 58 disposed above conductive films 601 to 606 are substantially equal to the relation in the distance between the lower portion of contact electrode group CA2 and the upper surfaces of stopper film 58 disposed above conductive films 607 to 612.

Further, the equation T11/r1=T12/r2 stands where T11 represents the thickness of adjustment film 700, r1 represents the etch rate of adjustment film 700 (silicon nitride film), T12 represents the depth of contact holes 901 to 906 from the upper surface of adjustment film 700, and r2 represents the etch rate of interlayer insulating film 18 (silicon oxide film). In other words, the etching of adjustment film 700 having thickness T11 and the etching of interlayer insulating film 18 having thickness T12 takes about the same amount of time.

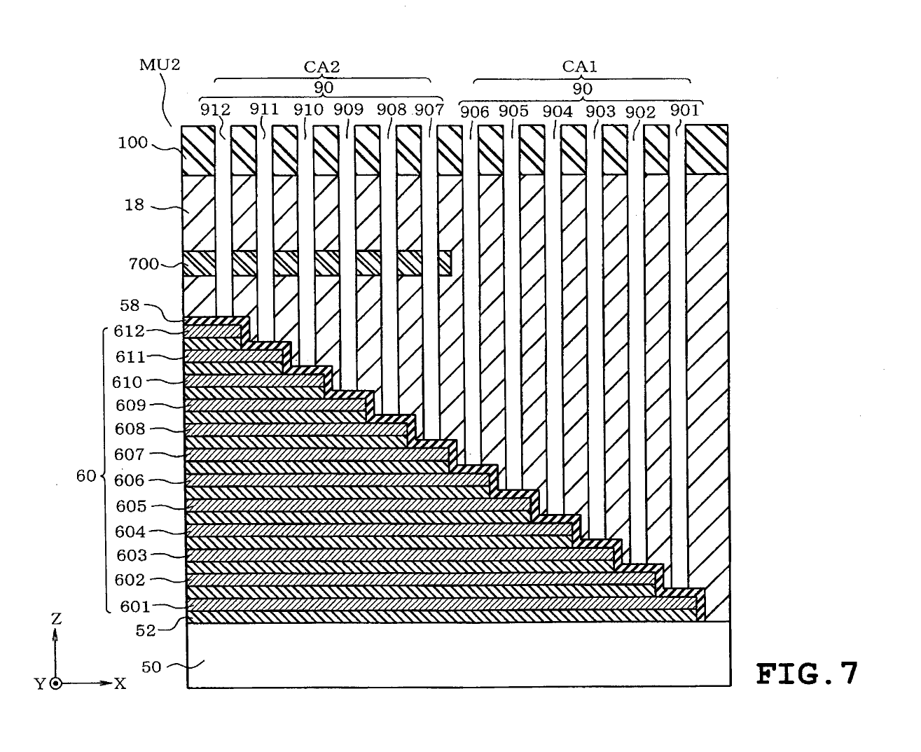

FIG. 7 illustrates the etching progressing to a point where the bottom portions of contact holes 901 to 912 have reached the surface of stopper film 58. As described earlier, stopper film 58 is formed of a silicon nitride film for example and interlayer insulating film 18 is formed of a silicon oxide film for example. The conditions applied to the etching is configured so that the etch rate of silicon nitride film is lower than the etch rate of silicon oxide film. This etch ratio (i.e. r2/r1) is hereinafter referred to as etch selectivity S. The etch rates of silicon oxide film and silicon nitride film may be specified to any value. Thus, etch selectivity S can be specified to any value. It is possible to prevent the etching from progressing through stopper film 58 and into the underlying films in shallow contact holes 90 by specifying an appropriate etch selectivity S. It is also possible to prevent the etching from progressing through stopper film 58 and into the underlying films in shallow contact holes 90 by configuring the thickness of stopper film 58 to a predetermined value or greater.

During the etching, the bottom surface of shallow contact hole 90 (such as 906) reaches the surface of stopper film 58 before the deep contact hole 90 (such as 901) belonging to the same contact electrode group CA. That is, while the etching of contact hole 901 is progressing through interlayer insulating film 18 (silicon oxide film), the etching of contact hole 906 progresses into stopper film 58 (silicon nitride film) which is etched with low etch rate. In other words, stopper film 58 located below shallow contact hole 90 is etched for longer period of time as compared to stopper film 58 located below deep contact hole 90.

When etch selectivity is represented by S, the thickness of stopper film 58 etched during the etching of contact hole 906 is 1/S of the thickness of interelectrode insulating film 18 etched during the etching of contact hole 901. Thus, contact hole 906 will not penetrate through stopper film 58 if the thickness of stopper film 58 is equal to or greater than 1/S of the difference in the depths of contact hole 906 and contact hole 901 (D1−D6). Stopper film 58 is formed in a sufficient thickness so as not to be etched through.

As described above, contact hole 906 is etched in greater amount as there is a difference in the depths of contact hole 901 and contact hole 906. In the etching performed in the first embodiment, if the difference in the depths of the contact holes are in the magnitude of the difference exemplified in contact hole 901 and contact hole 906, it is possible to prevent stopper film 58 from being etched through by specifying sufficient selectivity for interlayer insulating film 18 (silicon oxide film) relative to adjustment film 700 (silicon nitride film) and by giving sufficient thickness to stopper film 58 so as not to be etched through. The same is applicable to contact hole 907 and contact hole 912.

Even if the bottom surface of contact hole 90 penetrates through stopper film 58, stacked conductive films 60 will not become conductive with one another as long as contact hole 90 does not further penetrate through the underlying conductive film 60. Thus, device operation will not be affected (wires are not shorted) even if contact hole 90 extends through stopper film 58 as long as contact hole 90 does not extend through the underlying conductive film 60 and reach conductive film 60 in further underlying layer. Thus, it is not required for stopper film 58 to have a thickness that will not be etched through. Further, conductive film 60 may be used as a stopper film in which case stopper film 58 need not be formed. Thus, in the above described example, the etching condition may be specified to exhibit an etch selectivity that will not cause conductive film 60 (polysilicon) to be etched through while a silicon oxide film (interlayer insulating film 18) amounting to the difference in depth of contact hole 906 and contact hole 901 is being etched. Alternatively, the thickness of conductive film 60 may be increased so as not to be etched through. The above described arrangement prevents shallow contact holes from penetrating through stopper film 58 and further through conductive films 60 even if there are differences in depths between contact holes 901 to 906 and contact holes 907 to 912.

In the first embodiment, etch amount is adjusted by allowing the etching of relatively deep contact holes 901 to 906 (contact electrode group CA1) to progress while relatively shallow contact holes 907 to 912 (contact electrode group CA2) are being etched through adjustment film 700. As a result it is possible to substantially equalize the remaining etch amount (depth) of shallow contact electrode group CA2 at the moment shallow contact electrode group CA2 have been etched through adjustment film 700 with the remaining etch amount (depth) of deep contact electrode group CA1.

In the first embodiment, groups of contact holes 90 which do not penetrate through stopper film 58 even when the depths of contact holes are different are referred to as contact electrode group CA1 and contact electrode group CA2. That is, if the depth difference are of the magnitude of the difference in the depths of contact holes 901 to 906, the etch amount can be adjusted by stopper film 58. Thus, contact holes 90 do not penetrate through stopper film 58 and consequently do not reach the underlying films. Similarly, if the depth difference are of the magnitude of the difference in the depths of contact holes 907 to 912, the etch amount can be adjusted by stopper film 58. Thus, contact holes 90 do not penetrate through stopper film 58 and consequently do not reach the underlying films. In other words, it is possible to relax the difference in the depths of the contact holes of contact electrode group CA1 and contact electrode group CA2, which differ significantly, by the presence of adjustment film 700.

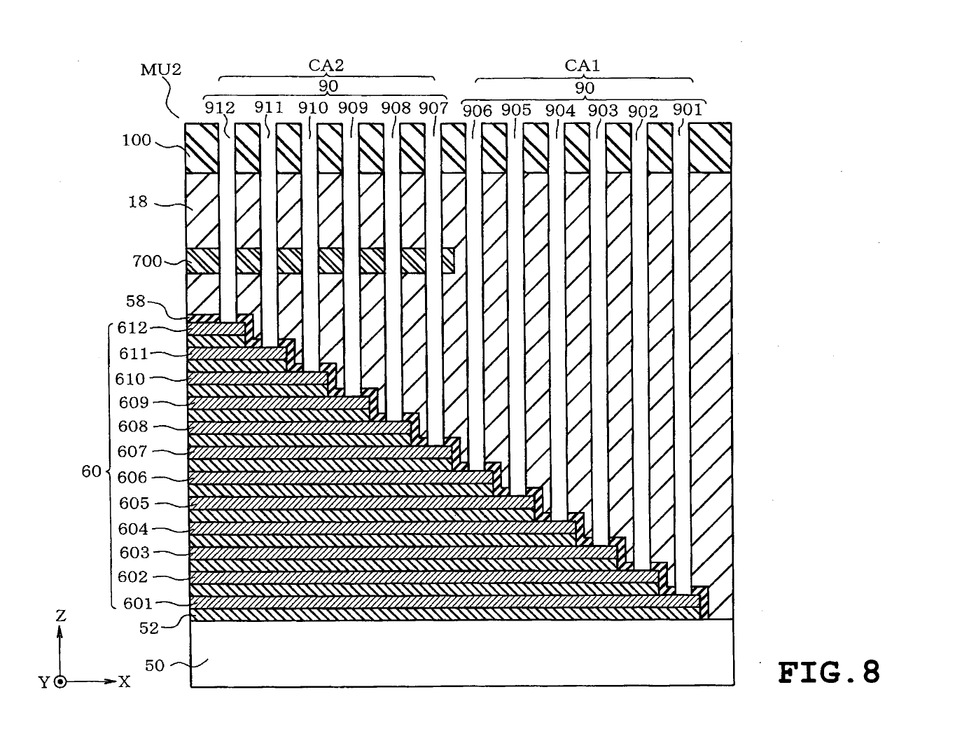

Next, as illustrated in FIG. 8, the stopper film 58 located at the bottom surface of contact hole 90 is etched away by RIE. As a result, contact holes 90 extend from the upper surface of interlayer insulating film 18 and through interlayer insulating film 18 so as to reach the upper surfaces of conductive films 601 to 612, respectively.

Next, as illustrated in FIG. 3, trenches for forming wirings 82 are formed above the upper portions of contact holes 90. Then, contact holes 90 are overfilled with a metal film so that the metal film further covers the upper surface of interlayer insulating film 18. Then, the metal film above interlayer insulating film 18 is removed by CMP. It is possible to form contact electrodes 80 and wirings 82 by the above described process steps. The metal film may be formed for example by forming a thin layer of titanium nitride (TiN) inside contact holes 90 and above the upper surface of interlayer insulating film 18 by CVD and thereafter forming tungsten (W) by CVD for example. Alternatively, metal film may be formed into contact plugs so as to fill contact holes 90, followed by formation of another metal film serving as the wiring layer which is thereafter removed from the upper surface of interlayer insulating film 18 by CMP to obtain wiring 82.

As described above, in the etching of contact holes 90 within the same contact electrode group CA, shallow contact hole 906 reaches the surface of stopper film 58 before deep contact hole 901 reaches the surface of stopper film 58. Contact hole 906 is etched in greater amount compared to contact hole 901 by the amount corresponding to the difference in the depths of contact hole 901 and contact hole 906.

In the etching of the first embodiment, if the depth difference is of the magnitude of the difference in the depths of contact hole 901 and contact hole 906, it is possible to make adjustments so that stopper film 58 is not etched through by specifying a sufficiently high selectivity for interlayer insulating film 18 (silicon oxide film) with respect to stopper film 58 (silicon nitride film) and by making stopper film 58 sufficiently thick. The same is applicable to contact holes 907 and 912. In simultaneously forming contact holes having significantly different depths in the first embodiment, contact electrode groups CA (CA1, CA2) are configured to include contact holes 90 which fall within the range of depth difference that can be adjusted by stopper film 58 so that the shallow contact holes 90 do not penetrate through stopper film 58.

However, the difference in the depths of contact holes 901 and 912 for example are significantly large. Thus, when simultaneously forming contact hole 901 and contact hole 912, the amount of stopper film 58 being etched when forming the shallow contact hole 912 is greater than the amount of stopper film 58 being etched when forming contact hole 901 by the amount corresponding to difference in the depths of contact hole 912 and contact hole 901. Thus, it is difficult to prevent stopper film 58 located at the bottom portion of contact hole 912 from being etched through. Further, there is a limit in the amount in which the thickness of stopper film 58 can be increased. Thus, it is difficult to simultaneously etch contact holes 901 to 912 while preventing stopper film 58 from being etched through.

In the first embodiment, adjustment film 700 is formed depending upon the depths of the contact holes of contact electrode groups CA. Contact holes 90 which fall within the range of depth difference that can be adjusted by stopper film 58 so that bottom surfaces thereof do not penetrate through stopper film 58 are grouped into contact electrode group CA1 and contact electrode group CA2. The regions for forming and not forming the above described adjustment film 700 is determined, and such regions are associated with contact electrode group CA1 and contact electrode group CA2 having different ranges of depths. Adjustment film 700 is not provided to the deep contact electrode group CA (CA1). Adjustment film 700 is provided to the shallow contact electrode group CA (CA2).

Thus, the relation of distance between the bottom surfaces of contact holes 90 of contact electrode group CA1 and the surfaces of the underlying structures (conductive films 60 and stopper film 58 thereabove) become equal to the relation of distance between the bottom surfaces of contact holes 90 of contact electrode group CA2 and the surfaces of the underlying structures (conductive films 60 and stopper film 58 thereabove) at the moment contact holes 90 penetrates through adjustment film 700. By providing adjustment film 700, the range of distance from the bottom surfaces of contact holes 90 to stopper film 58 may be adjusted for each of contact electrode group CA1 and contact electrode group CA2 so that stopper film 58 is not etched through. The above described structure allows contact holes 901 to 912 to be etched simultaneously while preventing stopper film 58 from being etched through. Any number of contact holes 90 may be provided in the same contact electrode group CA, and is therefore not limited to six described in the above example.

Contact electrode 80 may be formed in the above described manner.

The method of manufacturing a semiconductor device of the first embodiment allows contacts having significantly different depths to be formed simultaneously without causing penetration through the stopper film. More specifically, when simultaneously forming contact holes 90 for contact electrode group CA1 (deep contact group) and contact electrode group CA2 (shallow contact group) having significantly different depths, it becomes possible to adjust the amount of etching between contact holes 90 having different depths by providing adjustment film 700. That is, it is possible to relax the large difference in the depths of contact holes through adjustment of etch amount by arranging, for example, one or more contact electrode groups CA (contact electrode group CA2) to extend through adjustment film 700 and one or more contact electrode groups CA (contact electrode group CA1) to not extend through adjustment film 700. Thus, it is possible to prevent contact holes 90 from extending through the stopper layer.

In the first embodiment, stopper film 58 or the stack of stopper film 58 and conductive film 60 may be considered to serve as the etch stopper layer. Alternatively, conductive film 60 may be considered to serve as the stopper layer when stopper film 58 is not provided.

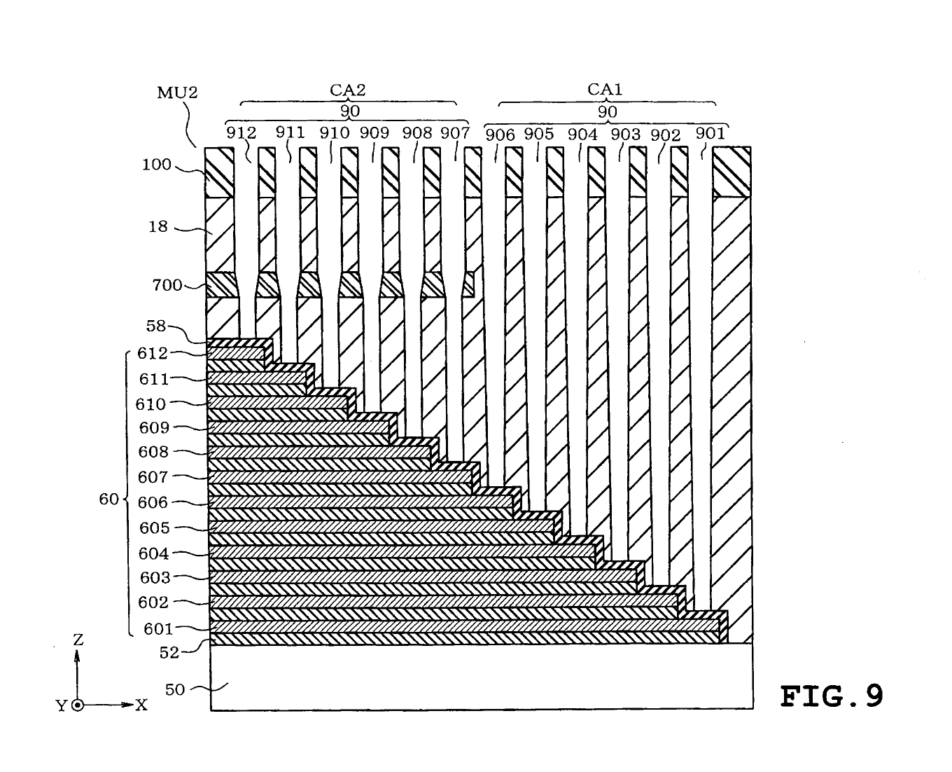

As illustrated in FIG. 9, contact holes 90 extending through adjustment film 700, that is, contact holes 907 to 912 belonging to contact electrode group CA2, may be tapered at locations extending through adjustment film 700. Thus, the diameters of contact holes 907 to 912 may become smaller toward the bottom surface of adjustment film 700 from the upper surface of adjustment film 700. On the other hand, contact holes 90 that do not extend through adjustment film 700 (contact electrode group CA1) may be gradually tapered toward the upper surfaces of conductive films 60 from the upper surface of interlayer insulating film 18. In the first embodiment, the etch rate of adjustment film 700 (formed of a silicon nitride film for example) is configured to be less than the etch rate of interlayer insulating film 18 (formed of a silicon oxide film for example).

Thus, the taper angles are larger in locations where contact holes 90 extend through adjustment film 700. In the absence of adjustment film 700, the bottom surfaces of shallow contact holes 90 and the bottom surfaces of deep contact holes 90 may have different diameters. However, by arranging the shallow contact group (contact electrode group CA2) to extend through adjustment film 700, it is possible to arrange the diameters of the bottom surfaces of contact holes 90 belonging to contact electrode group CA1 and the diameters of the bottom surfaces of contact holes 90 belonging to contact electrode group CA2 to be substantially equal. That is, it is possible to adjust the diameters of the holes of contact holes 90 by adjustment film 700. As a result, it is possible to reduce the variation of contact resistance of contact holes 901 to 912.

### Second Embodiment

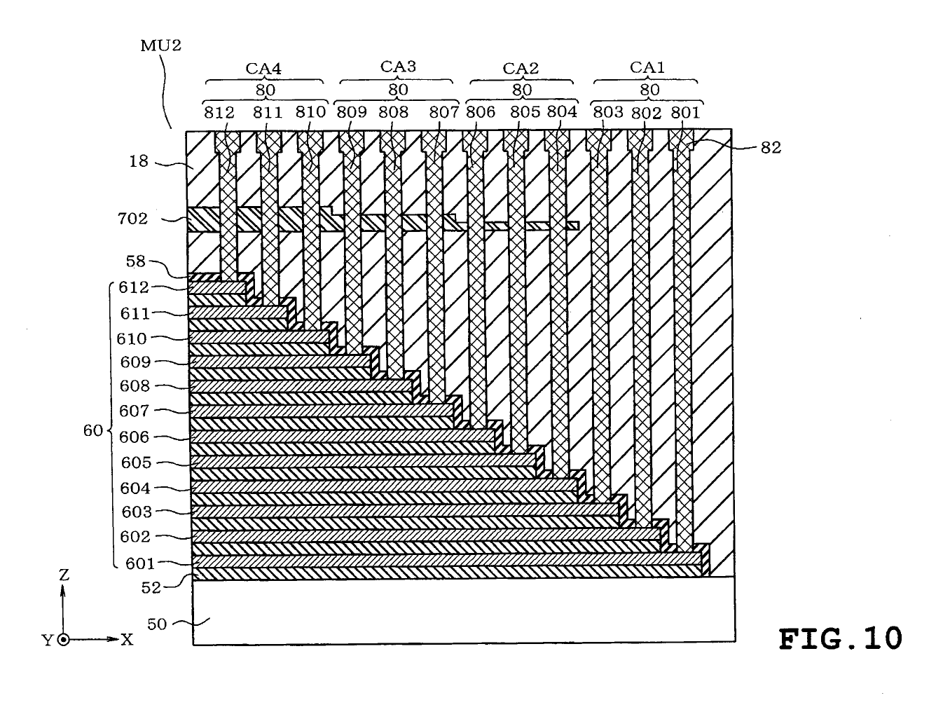

Next a description will be given on a second embodiment with reference to the drawings. FIG. 10 illustrates the second embodiment and is one example of a vertical cross-sectional view schematically illustrating the structure shaped like a stairway by conductive films 60 at wire connecting portion MU2 illustrated in FIG. 2B. FIG. 10 to FIG. 16 illustrate examples of 12 layers of conductive films 60 for convenience of explanation n; however, any number of conductive films 60 may be used.

In FIG. 10, twelve layers of conductive films 60 are provided as described above. Conductive film 60 in the lowermost layer is represented as conductive film 601, and subsequent layers are represented in sequence as conductive film 602, conductive film 603, and so forth, and conductive film 60 in the uppermost layer is represented as conductive film 612. Interelectrode insulating film 52 is provided between conductive films 60 for insulating conductive films 60. Conductive film 60 is formed of for example an amorphous silicon. The amorphous silicon may or may not be doped with impurities. A silicon oxide film may be used for example as interelectrode insulating film 52.

Stopper film 58 serving as a stopper layer is formed above the upper surfaces of conductive films 60 (601 to 612) arranged like a stairway. A silicon nitride film may be used for example as stopper film 58. Interlayer insulating film 18 is provided above stopper film 58. A silicon oxide film may be used for example as interlayer insulating film 18. Adjustment film (etching adjustment film) 702 is provided inside interlayer insulating film 18. A silicon nitride film or a densified silicon oxide film may be used for example as adjustment film 702.

Contact electrodes 80 (801 to 812) are formed in interlayer insulating film 18. Each of contact electrodes 801 to 803 extend through interlayer insulating film 18 and stopper film 58 and reach the surfaces of conductive films 601 to 603 from the surface of interlayer insulating film 18. Contact electrodes 801 to 803 do not extend through adjustment film 702. Contact electrodes 804 to 812 extend through interlayer insulating film 18, adjustment film 702, and stopper film 58 and reach the surfaces of conductive films 604 to 612 from the surface of interlayer insulating film 18. Contact electrode 80 is formed for example by a damascene process. Wire 82 is disposed at the upper portion of contact electrode 80 so as to be formed in one with the contact plug portion.

Contact electrodes 801 to 803 are collectively referred to as contact electrode group CA1, contact electrodes 804 to 806 are collectively referred to as contact electrode group CA2, contact electrodes 807 to 809 are collectively referred to as contact electrode group CA3, and contact electrodes 810 to 812 are collectively referred to as contact electrode group CA4. The depths of contact holes (contact electrodes) are the deepest in contact electrode group CA1, and become shallower in the order of CA2, CA3, and CA4. Contact electrode 804 being the deepest among the contact electrodes 80 belonging to contact electrode group CA2 is shallower than the shallowest contact electrode 803 among contact electrodes 80 belonging to contact electrode group CA1. Contact electrode 807 being the deepest among the contact electrodes 80 belonging to contact electrode group CA3 is shallower than the shallowest contact electrode 806 among contact electrodes 80 belonging to contact electrode group CA2. Contact electrode 810 being the deepest among the contact electrodes 80 belonging to contact electrode group CA4 is shallower than the shallowest contact electrode 809 among contact electrodes 80 belonging to contact electrode group CA3.

Adjustment film 702 is not formed in region where contact electrode group CA1 is formed. In contrast, adjustment film 702 is formed in regions where contact electrode group CA2, CA3, and CA4 are formed and contact electrodes 804 to 812 extend through adjustment film 702. Adjustment film 702 is formed of three regions each having different thicknesses. The region of adjustment film 702 where contact electrode group CA2 is formed is the thinnest. The region of adjustment film 702 where contact electrode group CA4 is formed is the thickest. The region of adjustment film 702 where contact electrode group CA3 is formed is disposed between contact electrode group CA2 and contact electrode group CA4 and has an intermediate thickness substantially in between the thicknesses of the regions where contact electrode group CA2 and contact electrode CA4 are formed. The thickness of adjustment film 702 is configured to vary depending upon the depths of contact electrodes 80 extending through it. That is, the thickness of adjustment film 70 becomes smaller (thinner) as contact electrode 80 becomes deeper and greater (thicker) as contact electrode 80 becomes shallower. It is possible to prevent penetration, or the like of the underlying layers, originating from the difference in the depths of contact electrodes 80 by configuring contact electrodes 80 to extend through adjustment film 702 having varying thicknesses depending upon the depths of contact electrodes 80.

Next, a manufacturing method of the second embodiment will be described with reference to FIG. 10 to FIG. 16. FIG. 10 to FIG. 16 are examples of vertical cross-sectional views illustrating the manufacturing process flow of the second embodiment. FIG. 10 to FIG. 16 are vertical cross-sectional views of wire connecting portions MU2 and illustrate the sequence of process steps involved in connecting contact electrodes 80 (801 to 812) to the upper surfaces of conductive films 60 (601 to 612).

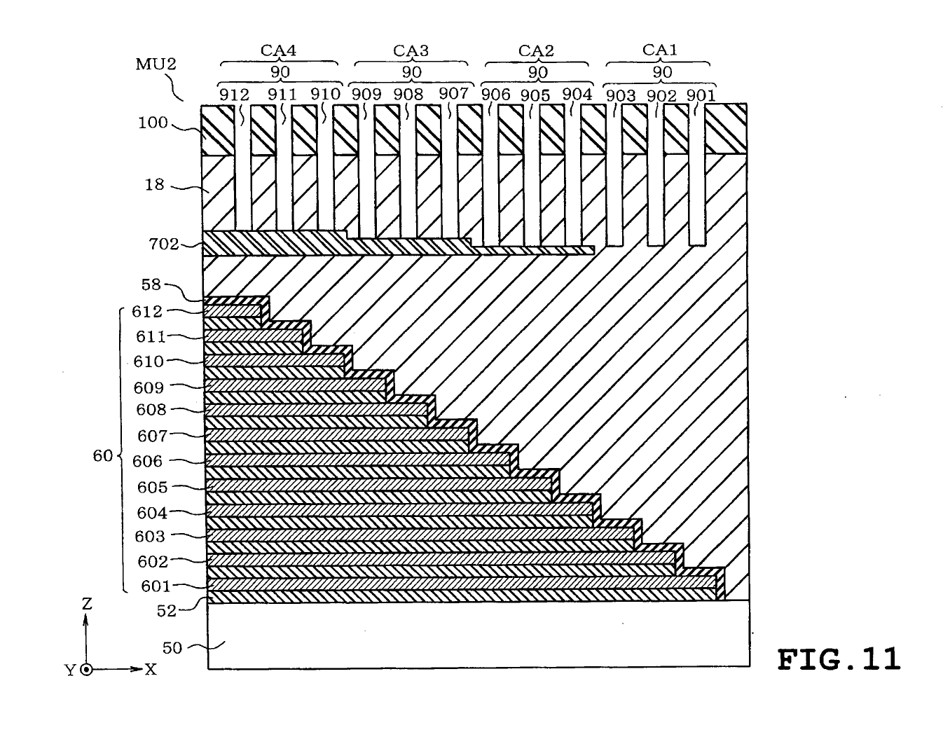

First, as illustrated in FIG. 11, interelectrode insulating film 52 and conductive films 60 are stacked above semiconductor substrate 50 and the structure is processed into a shape of stairway. The process steps carried out prior to the formation of adjustment film 702 are substantially the same as those described with reference to FIG. 4.

Next, adjustment film 702 is formed. For example, adjustment film 702 may be obtained by forming a silicon nitride film by CVD and patterning the silicon nitride film using lithography and RIE. Adjustment film 702 is not formed in the region where contact electrode group CA1 is formed. The thickness of adjustment film 702 is the smallest (thinnest) in the region where contact electrode group CA2 is formed, and the largest (thickest) in the region where contact electrode group CA4 is formed. The region of adjustment film 702 where contact electrode group CA3 is formed has an intermediate thickness substantially in between the thicknesses of the regions where contact electrode group CA2 and contact electrode CA4 are formed. In other words, adjustment film 702 as a whole is shaped like a stairway.

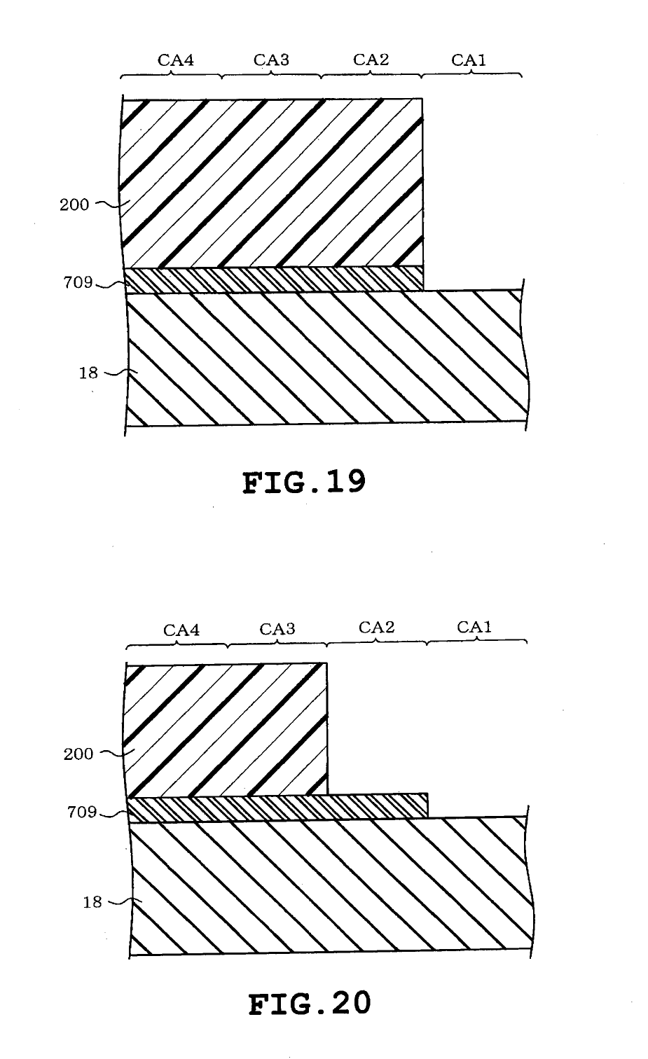

The following method may be employed in forming the stairway shape of adjustment film 702. The method of forming the stairway shape of adjustment film 702 is described hereinafter through vertical cross-sectional views of FIG. 19 to FIG. 23 each schematically illustrating the process steps involved. First, as illustrated in FIG. 19, silicon nitride film 709 is formed by CVD above interlayer insulating film 18 formed above semiconductor substrate 50. Silicon nitride film 709 is transformed into adjustment film 702 shaped like a stairway through the process steps described below. Silicon substrate 50 is not illustrated in FIG. 19 to FIG. 23. Interlayer insulating film 18 is formed by CVD.

Next, the surface of interlayer insulating film 18 is planarized by CMP. Then, resist 200 is formed which is thereafter patterned by lithography. The edge of resist 200 is located at the edge of the region where contact electrode group CA2 is formed (the boundary with the region where contact electrode group CA1 is formed). Then, using resist 200 as a mask, silicon nitride film 709 is removed by RIE. RIE may be performed under anisotropic conditions. Thus, silicon nitride film 709 located in the region for forming contact electrode group CA1 is removed.

Next, as illustrated in FIG. 20, resist 200 is receded by slimming so that the edge of resist 200 is located at the edge of the region for forming contact electrode group CA3 (the boundary with the region for forming contact electrode group CA2).

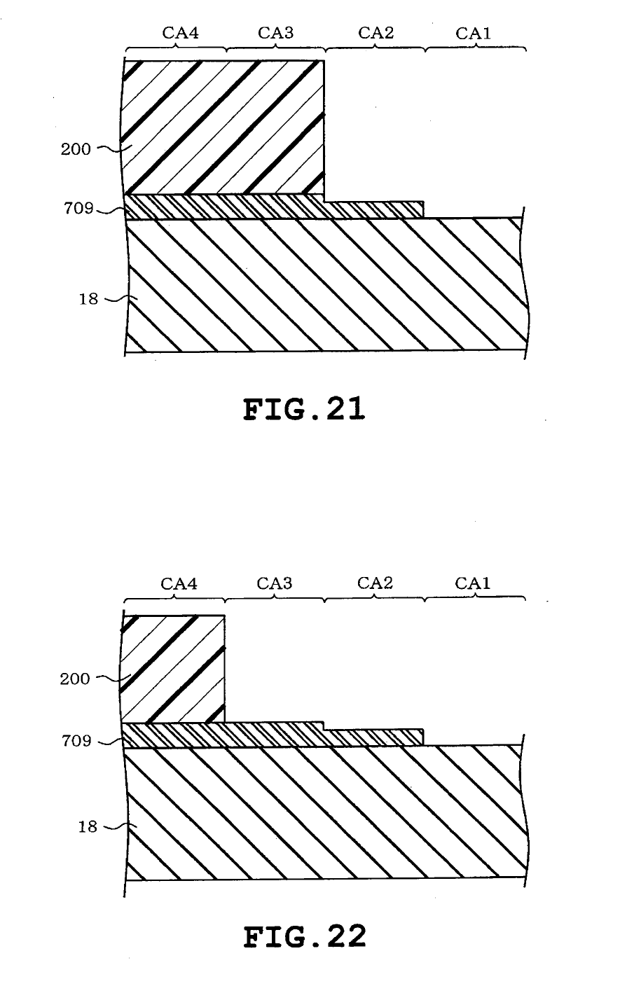

Then, as illustrated in FIG. 21, approximately ⅓ of the thickness of silicon nitride film 709 for example is etched by RIE using resist 200 as a mask. As a result, the thickness of silicon nitride film 709 in the region for forming contact electrode CA2 is reduced to approximately ⅔ of its original thickness.

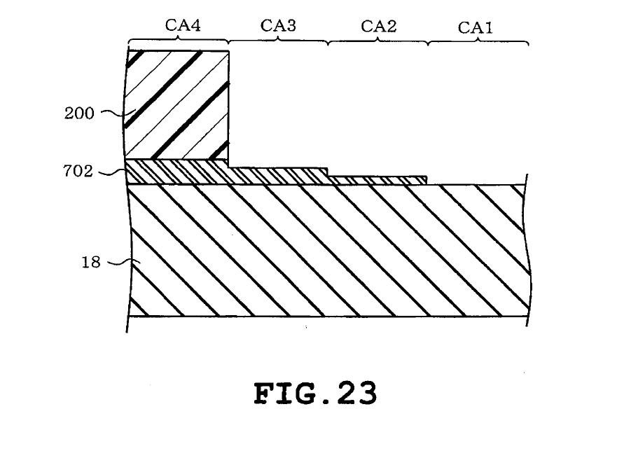

Then, as illustrated in FIG. 22, resist 200 is receded by slimming so that the edge of resist 200 is located at the edge of the region for forming contact electrode group CA4 (the boundary with the region for forming contact electrode group CA3). Next, as illustrated in FIG. 23, approximately ⅓ of the thickness of silicon nitride film 709 for example is etched by RIE using resist 200 as a mask. As a result, the thickness of silicon nitride film 709 located in the region for forming contact electrode CA3 is reduced to approximately ⅔ of its original thickness. Further, silicon nitride film 709 located in the region for forming contact electrode group CA2 is reduced to approximately ⅓ of its original thickness. It is possible to form adjustment film 702 into a shape of a stairway in the above described manner. Resist 200 may be patterned by lithography for each instance of etching instead of slimming resist 200.

Next, as illustrated in FIG. 11, interlayer insulating film 18 is formed and the upper surface of interlayer insulating film 18 is planarized by CMP. Then, mask 100 is formed which is used for forming a contact. A resist formed by lithography may be used as mask 100. Further, a carbon film patterned by lithography for example may be used as mask 100 instead of the resist.

Next, contact holes 90 (901 to 912) are formed by RIE using mask 100 as an etch mask. FIG. 11 illustrates the ongoing formation of contact holes 90 and more specifically illustrates the state in which the formation of contact holes 90 of contact electrode group CA2 have progressed to the height of the upper surface of adjustment film 702. The conditions applied in the etching is configured so that the etch rate silicon nitride film serving as adjustment film 702 is less than the etch rate of silicon oxide film serving as interlayer insulating film 18. Etching of contact holes 90 (904 to 912) of contact electrode CA2, CA3, and CA4 is stopped on the upper surface of adjustment film 702. The heights of the upper surfaces of stopper film 58 located in the regions for forming contact electrode group CA3 and contact electrode group CA4 are high. Thus, the bottom surfaces of contact holes 90 (907 to 912) of contact electrode group CA3 and contact electrode group CA4 reach the surface of adjustment film 702 before contact holes 90 of contact electrode group CA2, and therefore are etched in greater amount compared to contact holes 90 of contact electrode group CA2. However, the difference is very little and thus, there is substantially no etching of adjustment film 702 at this point in time at the lower surfaces of contact holes 904 to 912.

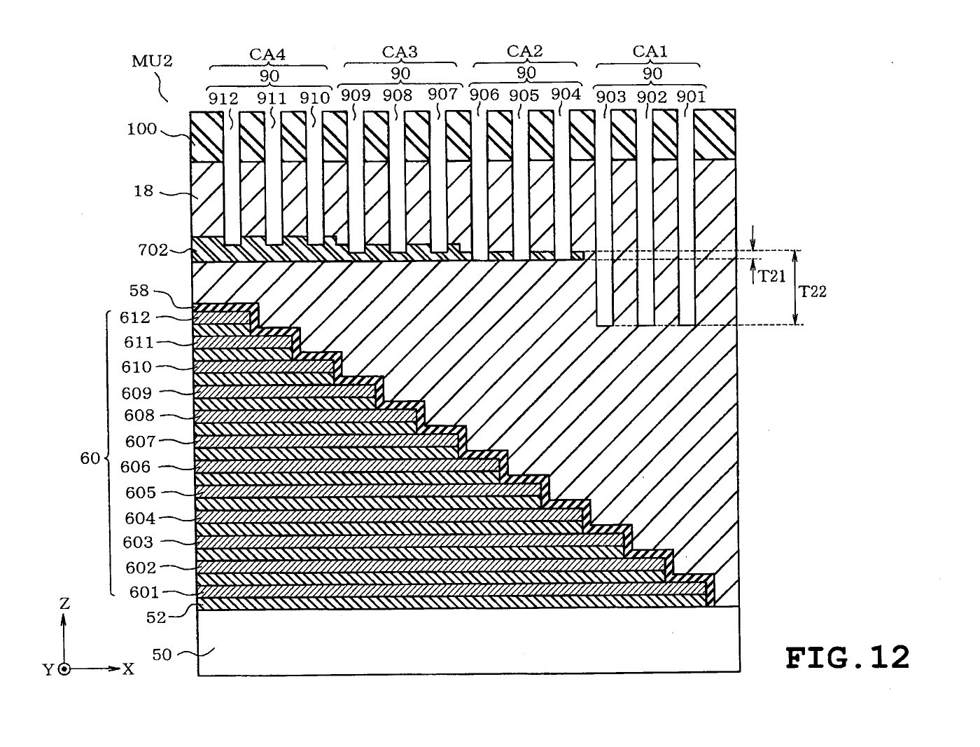

FIG. 12 illustrates the etching progressing to the point where contact holes 904 to 906 of contact electrode group CA2 have penetrated through adjustment film 702. FIG. 12 further illustrates etching for forming contact holes 901 to 903 of contact electrode group CA1 progressing further downward within interlayer insulating film 18 as compared to contact holes 904 to 906.

The equation T21/r1=T22/r2 stands where T21 represents the thickness of adjustment film 702 located in the region for forming contact electrode group CA2, r1 represents the etch rate of adjustment film 702 (silicon nitride film), T22 represents the depth of contact holes 901 to 903 from the upper surface of adjustment film 702 located in the region for forming contact electrode group CA2 to the bottom surfaces of contact holes 901 to 903, and r2 represents the etch rate of interlayer insulating film 18 (silicon oxide film). In other words, the etching of adjustment film 702 having thickness T21 and the etching of interlayer insulating film 18 having thickness T22 takes about the same amount of time. Meanwhile, approximately T21 of adjustment film 702 is etched at the bottom portions of contact holes 907 to 912 belonging to contact electrode groups CA3 and contact electrode group CA4.

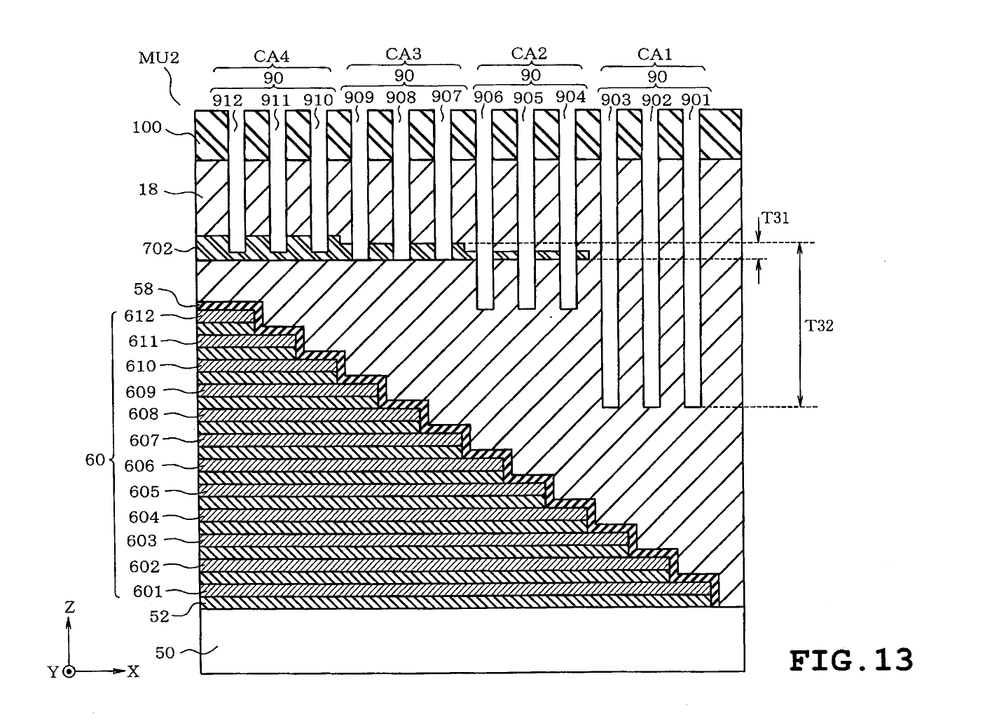

FIG. 13 illustrates the etching progressing to the point where contact holes 907 to 909 of contact electrode group CA3 have penetrated through adjustment film 702. FIG. 13 further illustrates etching for forming contact holes 901 to 906 of contact electrode group CA1 and contact electrode group CA2 progressing further downward within interlayer insulating film 18 as compared to contact holes 907 to 909.

Further, the equation T31/r1=T32/r2 stands where T31 represents the thickness of adjustment film 702 located in the region for forming contact electrode group CA3, r1 represents the etch rate of adjustment film 702 (silicon nitride film), T32 represents the depth of contact holes 901 to 903 from the upper surface of adjustment film 702 located in the region for forming contact electrode group CA3 to the lower surfaces of contact holes 901 to 903, and r2 represents the etch rate of interlayer insulating film 18 (silicon oxide film). In other words, the etching of adjustment film 702 having thickness T31 and the etching of interlayer insulating film 18 having thickness T32 takes about the same amount of time.

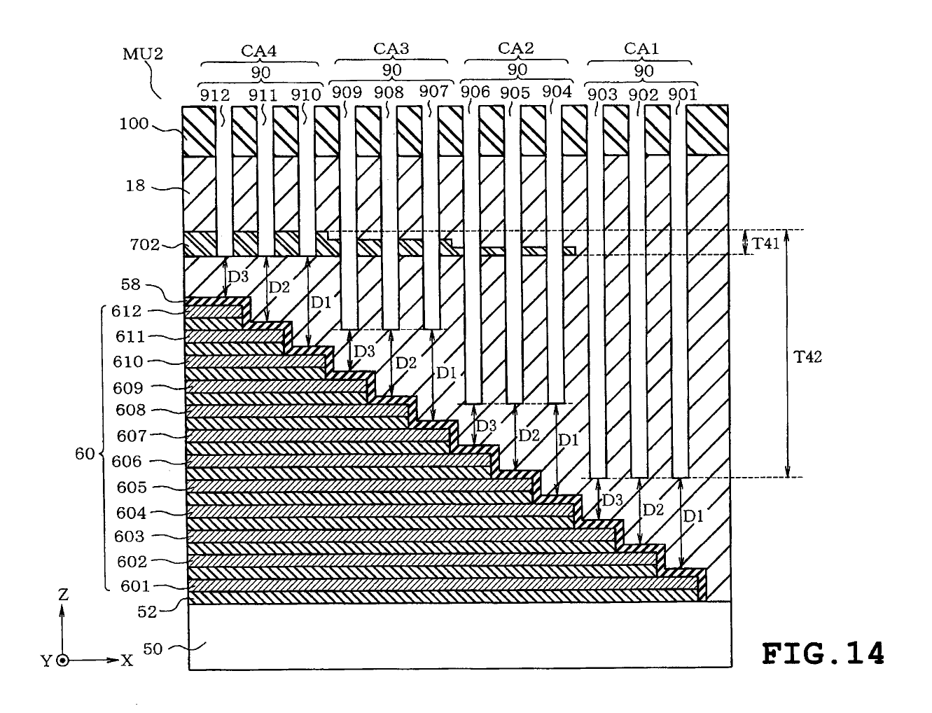

FIG. 14 illustrates the etching progressing to the point where contact holes 910 to 912 have penetrated through adjustment film 702 located in the region for forming contact electrode group CA4. FIG. 14 further illustrates etching for forming contact holes 901 to 909 of contact electrode group CA1, CA2, and CA3 progressing further downward within interlayer insulating film 18 as compared to contact holes 910 to 912.

Further, the equation T41/r1=T42/r2 stands where T41 represents the thickness of adjustment film 702 located in the region for forming contact electrode group CA4, r1 represents the etch rate of adjustment film 702 (silicon nitride film), T42 represents the depth of contact holes 901 to 903 from the upper surface of adjustment film 702 located in the region for forming contact electrode group CA4 to the lower surfaces of contact holes 901 to 903, and r2 represents the etch rate of interlayer insulating film 18 (silicon oxide film). In other words, the etching of adjustment film 702 having thickness T41 and the etching of interlayer insulating film 18 having thickness T42 takes about the same amount of time.

As illustrated in FIG. 14, when the distances between the bottom surfaces of contact holes 901, 902, and 903 to the upper surface of stopper film 58 above conductive films 601, 602, and 603 are represented as D1, D2, and D3, respectively, the distances between the bottom surfaces of contact holes 904, 905, and 906, to the upper surface of stopper film 58 above conductive films 604, 605, and 606 are substantially equal to D1, D2, and D3, respectively. Similarly, the distances between the bottom surfaces of contact holes 907, 908, and 909, to the upper surface of stopper film 58 above conductive films 607, 608, and 609 are substantially equal to D1, D2, and D3, respectively and the distances between the bottom surfaces of contact holes 910, 911, and 912, to the upper surface of stopper film 58 above conductive films 610, 611, and 612 are substantially equal to D1, D2, and D3, respectively.

That is, when the contact electrodes are referred to by the group in which they belong, the relation in the distance between the lower portions of contact holes 90 of contact electrode group CA1 (the group of deepest contact holes), contact electrode group CA2 (the group of deep contact holes), contact electrode group CA3 (the group of shallow contact holes), contact electrode group CA4 (the group of the shallowest contact holes) and conductive films 601 to 612 are substantially the same. More specifically, the relation in the distance between the lower portion of contact electrode group CA1 to the upper surfaces of stopper film 58 disposed above conductive films 601 to 603; the relation in the distance between the lower portion of contact electrode group CA2 to the upper surfaces of stopper film 58 disposed above conductive films 604 to 606; the relation in the distance between the lower portion of contact electrode group CA3 to the upper surfaces of stopper film 58 disposed above conductive films 607 to 609; the relation in the distance between the lower portion of contact electrode group CA4 to the upper surfaces of stopper film 58 disposed above conductive films 610 to 612 are substantially the same. In the second embodiment, contact holes or contact electrodes having different depths are arranged into multiple contact (electrode) groups depending upon their depths in the above described manner.

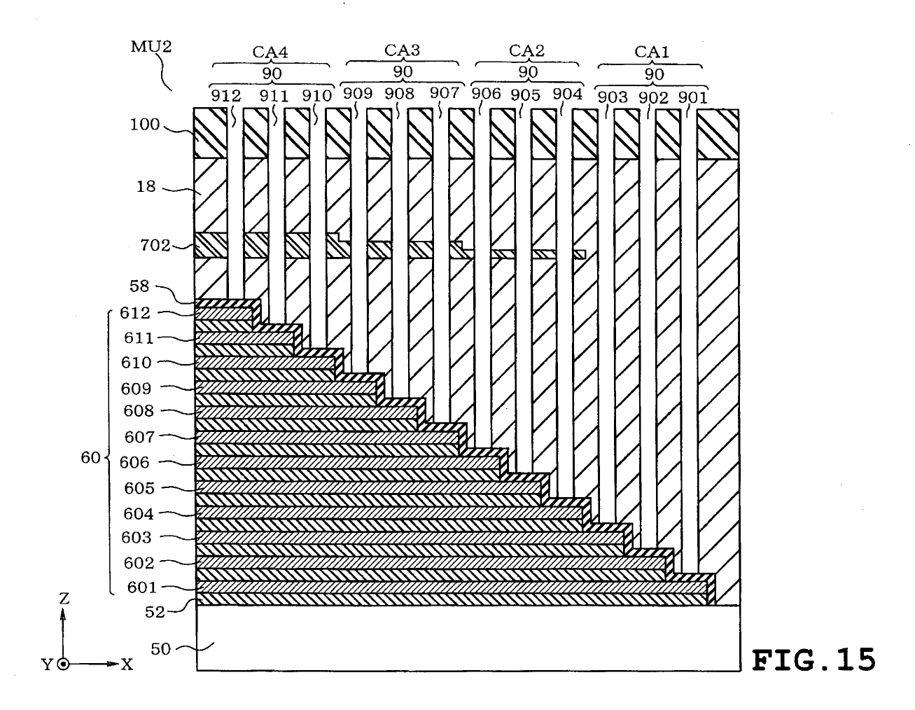

FIG. 15 illustrates the etching progressing to a point where the bottom portions of contact holes 901 to 912 have reached the surface of stopper film 58. As described earlier, stopper film 58 is formed of a silicon nitride film for example and interlayer insulating film 18 is formed of a silicon oxide film for example. The conditions applied to the etching is configured so that the etch rate of silicon nitride film is lower than the etch rate of silicon oxide film. It is possible to stop the etching on stopper film 58 and prevent the etching from progressing into the underlying films by configuring the thickness of stopper film 58 to a predetermined value or greater.

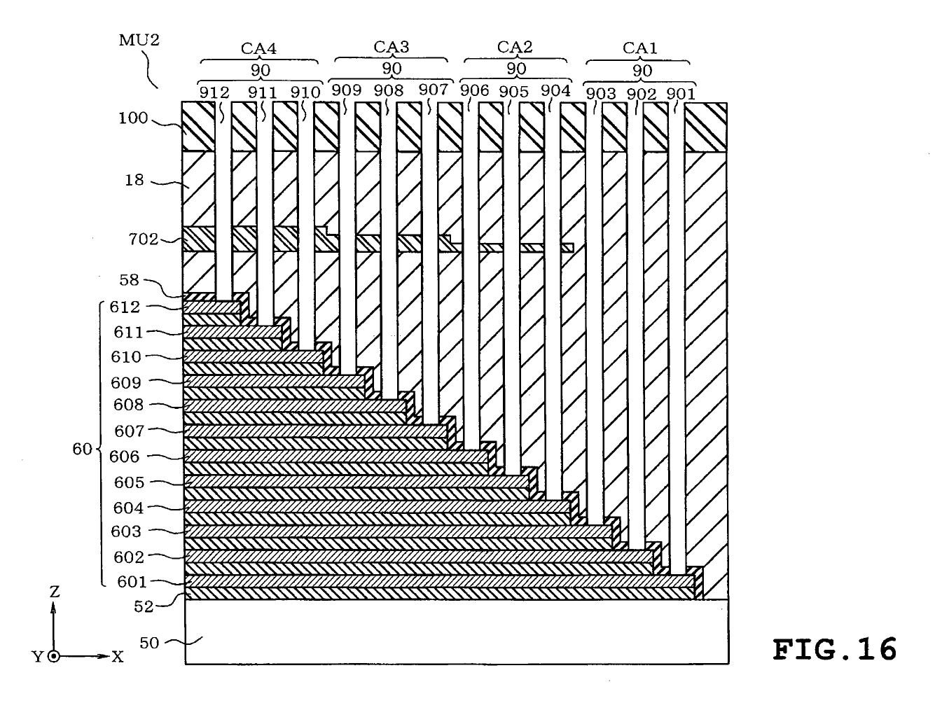

Next, as illustrated in FIG. 16, the stopper film 58 located at the bottom surfaces of contact holes 90 is etched away by RIE. As a result, contact holes 90 (901 to 912) extend from the upper surface of interlayer insulating film 18 and through interlayer insulating film 18 so as to reach the upper surfaces of conductive films 601 to 612, respectively.

Next, as illustrated in FIG. 10, trenches for forming wirings 82 are formed above the upper portions of contact holes 90. Then, contact holes 90 are overfilled with a metal film so that the metal film further covers the upper surface of interlayer insulating film 18. Then, the metal film above interlayer insulating film 18 is removed by CMP. It is possible to fill contact holes 90 with the metal film and form contact electrodes 80 and wirings 82 by the above described process steps.

As described above, in the etching of contact holes 90, shallow contact hole 903 reaches the surface of stopper film 58 before deep contact hole 901 reaches the surface of stopper film 58. Contact hole 903 is etched in greater amount compared to contact hole 901 by the amount corresponding to the difference in the depths of contact hole 901 and contact hole 903.

In the etching of the second embodiment, if the depth difference is of the magnitude of the difference in the depths of contact hole 901 and contact hole 903, it is possible to make adjustments so that stopper film 58 is not etched through by specifying a sufficiently high selectivity for interlayer insulating film 18 (silicon oxide film) with respect to stopper film 58 (silicon nitride film) and by making stopper film 58 sufficiently thick. In simultaneously forming contact holes having significantly different depths in the second embodiment, contact electrode groups CA (CA1, CA2, CA3, and CA4) are configured to include contact holes 90 which fall within the range of depth difference that can be adjusted by stopper film 58 so that the bottom surfaces of shallow contact holes 90 do not penetrate through stopper film 58.

However, the difference in the depths of contact holes 901 and 912 for example are significantly large. Thus, when simultaneously forming contact hole 901 and contact hole 912, the amount of stopper film 58 being etched when forming the shallow contact hole 912 is greater than the amount of stopper film 58 being etched when forming contact hole 901 by the amount corresponding to difference in the depths of contact hole 912 and contact hole 901. Thus, it is difficult to prevent stopper film 58 located at the bottom portion of contact hole 912 from being etched through. Further, there is a limit in the amount in which the thickness of stopper film 58 can be increased. Thus, it is difficult to simultaneously etch contact holes 901 to 912 while preventing stopper film 58 from being etched through.

In the second embodiment, adjustment film 702 is shaped like a stairway so as to include multiple regions having different thicknesses. The regions of adjustment film 702 having different thicknesses are associated with contact electrode group CA1, CA2, CA3, and CA4 having different depths. More specifically, the deepest contact electrode group CA (CA1) is not provided with adjustment film 702. Contact electrode group CA (CA2) having the second greatest depth is associated with the portion of adjustment film 702 having the least thickness. Contact electrode group CA (CA3) having the third greatest depth is associated with the portion of adjustment film 702 having the second least thickness. Contact electrode group CA (CA4) having the fourth greatest depth is associated with the portion of adjustment film 702 having the greatest thickness.

Thus, the relation of distance between the bottom surfaces of contact holes 90 of contact electrode group CA1, CA2, CA3, and CA4 and the surfaces of the underlying structures (conductive films 60 and stopper film 58 thereabove) become the same at the moment contact holes 90 penetrate through adjustment film 702. By providing stopper film 58, the range of distance from the bottom surfaces of contact holes 90 to stopper film 58 may be adjusted within the same contact electrode group CA so that stopper film 58 is not etched through. The above described structure allows contact holes 901 to 912 having significantly different depths to be etched simultaneously while preventing stopper film 58 from being etched through.

Further, as compared to the first embodiment, the second embodiment allows process margin for preventing penetration to be controlled more elaborately by increasing the number of contact electrode groups CA and more finely controlling the thickness of adjustment film 702 depending upon contact electrode group CA. Because the difference in the depths of contact holes 90 within the same contact electrode group CA can be reduced, it is possible to reduce the thickness of stopper film 58 and thereby simplify the process.

Any number of contact holes 90 may be provided in the same contact electrode group CA, and is therefore not limited to three described in the above example. Stopper film 58, the stack of stopper film 58 and conductive film 60, or conductive film 60 may be considered to serve as the etch stopper layer in the second embodiment as well.

### Third Embodiment

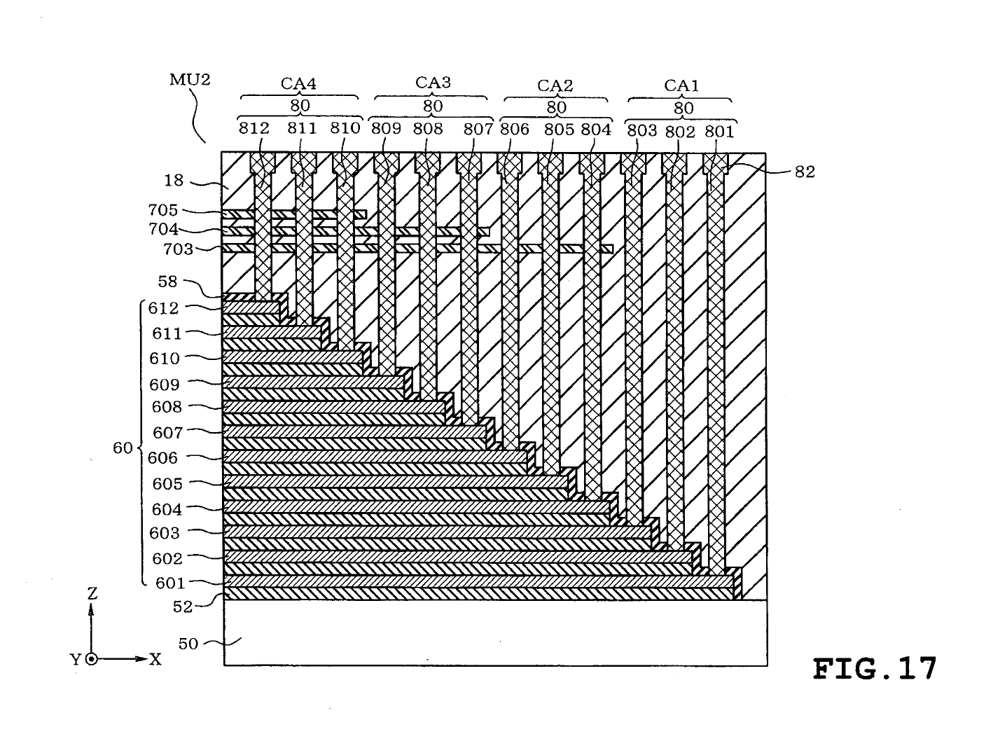

Next, a description will be given on a third embodiment with reference to the drawings. FIG. 17 describes the structure of the third embodiment and is one example of a vertical cross sectional view schematically illustrating the stairway structure formed by conductive film 60 in wire connecting portion MU2 illustrated in FIG. 2B. FIG. 17 illustrates twelve layers of conductive films 60 for convenience of explanation. However, any number of conductive films 60 may be provided as was the case in the first and the second embodiment.

The third embodiment differs from the second embodiment in that adjustment films (etching adjustment films) 703, 704, and 705 are provided as separate films. Adjustment film 703 is formed so as to extend across contact electrode group CA2 to contact electrode group CA4. Adjustment film 704 is formed so as to extend across contact electrode group CA3 to contact electrode group CA4. Adjustment film 705 is formed in the region for forming contact electrode group CA4. Thus, contact electrode group CA2 penetrates one layer, namely adjustment film 703. Contact electrode group CA3 penetrates two layers, namely adjustment film 703 and adjustment film 704. Contact electrode group CA4 penetrates three layers, namely adjustment film 703, adjustment film 704, and adjustment film 705. Relatively deep contact holes 90 are configured so as not to penetrate any adjustment films 70 or so as to penetrate relatively small number of adjustment films 70. Relatively shallow contact holes 90 are configured to penetrate relatively large number of adjustment films 70. That is, in the third embodiment, the number of films penetrated by the contact electrode group is varied depending upon the depth of the contact electrode group. Thus, the amount of etching is controlled by varying the thickness of the films penetrated by the contact electrode group. As a result, it is possible to provide effects similar to those of the second embodiment.

### Fourth Embodiment

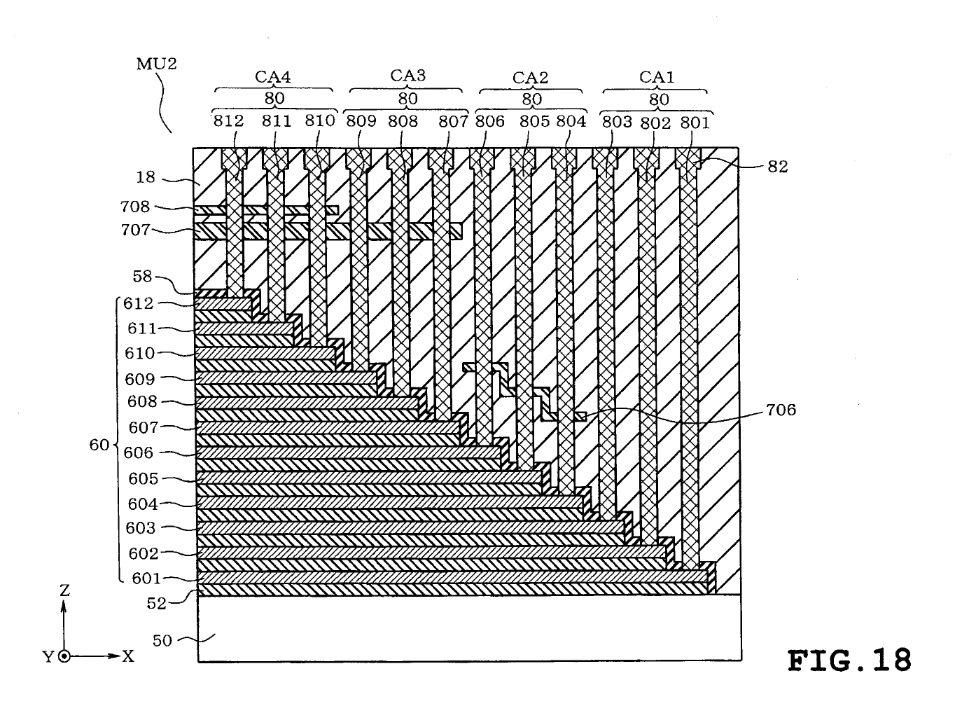

Next, a description will be given on a fourth embodiment with reference to the drawings. FIG. 18 describes the structure of the fourth embodiment and is one example of a vertical cross sectional view schematically illustrating the stairway structure formed by conductive film 60 in wire connecting portion MU2 illustrated in FIG. 2B. FIG. 18 illustrates twelve layers of conductive films 60 for convenience of explanation. However, any number of conductive films 60 may be provided as was the case in the first, the second, and the third embodiment.

The fourth embodiment differs from the second embodiment in that adjustment films (etching adjustment films) 706, 707, and 708 are provided. Adjustment film 706 is formed in the region for forming contact electrode group CA2. Adjustment film 706 is formed in a position lower than the height of the uppermost layer of conductive film 60 (612). Adjustment film 707 is formed so as to extend across contact electrode group CA3 to contact electrode group CA4. Adjustment film 708 is formed in the region for forming contact electrode group CA4. The fourth embodiment is described through an example in which the thickness of adjustment film 707 is greater than the thicknesses of adjustment film 706 and adjustment film 708. This is intended to make relatively shallower contact electrode group CA to penetrate relatively thicker adjustment films 70 as compared to relatively deeper contact electrode group CA. The thickness of adjustment film 70 may be configured to vary as described above. That is, the total thickness of adjustment films 70 penetrated by a relatively shallow contact electrode group CA may be configured to a relatively large value. In contrast, the total thickness of adjustment films 70 penetrated by a relatively deep contact electrode group CA may be configured to relatively small value. In the fourth embodiment, the amount of etching is controlled by varying the thickness of adjustment film 70 as required.

Further, adjustment film 70 (706) may be formed at a location lower than the height of conductive film 60 in the uppermost layer. As a result, it is possible to improve the flexibility of the process.

Further, the fourth embodiment provides effects similar to those of the second embodiment.

### Other Embodiments

Stacked-type nonvolatile semiconductor storage device may be shaped for example like a letter U or a letter I. In the above described embodiments, a stacked-type nonvolatile semiconductor storage device shaped like a letter U is described as an example. However, embodiments may be described through a stacked-type nonvolatile semiconductor storage device shaped like a letter I as well.

In the embodiments described above, description is given through an example in which the thicknesses of adjustment films 700 (700 to 708) are varied depending upon the depths of the contact openings of the contact electrode groups CA significantly varying from one another. Alternatively, there may only be one contact hole for example in which the depth significantly varies. For example, adjustment films 700 (700 to 708) may be provided for the single contact hole.

Embodiments described above may be applied to a NAND or a NOR-type flash memory, EPROM, DRAM, SRAM, other types of semiconductor storage devices, or various types of logic devices, and to manufacturing process steps of other types of semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stack of conductive films, the stack of conductive films having a stairway portion located at an end portion thereof;
an insulating layer disposed above the stack of conductive films;
contact electrodes having different depths extending from an upper surface of the insulating layer to establish connection with upper surfaces of the conductive films in the stairway portion, the contact electrodes having different depths being arranged into at least a first contact group and a second contact group;
an adjustment film disposed in the insulating layer;
the contact electrodes in the second contact group extending through the adjustment film,
a contact electrode having the smallest depth in the first contact group being deeper than a contact electrode having the greatest depth in the second contact group.

2. The semiconductor device according to claim 1, wherein the contact electrodes in the first contact group do not extend through the adjustment film.

3. The semiconductor device according to claim 1, wherein the adjustment film includes at least a region having a first thickness and a region having a second thickness, and wherein the contact electrodes in the first contact group extend through the region of the adjustment film having the first thickness, and the contact electrodes in the second contact group extend through the region of the adjustment film having the second thickness.

4. The semiconductor device according to claim 3, wherein the contact electrodes having different depths are further arranged into a third contact group, and wherein a contact electrode having the smallest depth in the third contact group is deeper than a contact electrode having the greatest depth in the first contact group, and wherein the contact electrodes in the third contact group do not extend through the adjustment film.

5. The semiconductor device according to claim 1, wherein the adjustment film includes at least a first region having a first thickness and a second region having a second thickness, and wherein the adjustment film is formed in one and is shaped like a stairway.

6. The semiconductor device according to claim 5, wherein the contact electrodes in the first contact group do not extend through the adjustment film.

7. The semiconductor device according to claim 5, wherein the contact electrodes in the first contact group extend through the first region of the adjustment film and the contact electrodes in the second contact group extend through the second region of the adjustment film.

8. The semiconductor device according to claim 7, wherein the contact electrodes having different depths are further arranged into a third contact group, and wherein a contact electrode having the smallest depth in the third contact group is deeper than a contact electrode having the greatest depth in the first contact group, and wherein the contact electrodes in the third contact group do not extend through the adjustment film.

9. The semiconductor device according to claim 8, wherein the conductive films are configured as word lines of a stacked-type nonvolatile semiconductor storage device.

10. The semiconductor device according to claim 1, wherein the adjustment film is divided in a depth direction into a plurality of portions.

11. The semiconductor device according to claim 10, wherein the adjustment film includes at least a first region having a first number of overlapping portions overlapping in a direction in which the contact electrodes extend and a second region having a second number of overlapping portions overlapping in a direction in which the contact electrodes extend, and wherein the contact electrodes in the first contact group extend through the first region of the adjustment film and the contact electrodes in the second contact group extend through the second region of the adjustment film.

12. The semiconductor device according to claim 11, wherein the contact electrodes having different depths are further arranged into a third contact group, and wherein a contact electrode having the smallest depth in the third contact group is deeper than a contact electrode having the greatest depth in the first contact group, and wherein the contact electrodes in the third contact group do not extend through the adjustment film.

13. The semiconductor device according to claim 12, wherein the conductive films are configured as word lines of a stacked-type nonvolatile semiconductor storage device.

14. A method of manufacturing a semiconductor device comprising:
forming a stack of conductive films and interelectrode insulating films above a semiconductor substrate;
forming a stairway portion by processing the conductive films and the interelectrode insulating films at an end portion of the stack of films;
forming an insulating film including an adjustment film above the stack of films including the stairway portion;
forming contact holes having different depths so as to extend from an upper surface of the insulating film and establish connection with upper surfaces of the conductive films and so that the contact holes are arranged into contact groups depending upon depths of the contact holes, contact holes in the deepest contact group among the contact groups do not extend through the adjustment film, and contact holes in other one or more contact groups extend through the adjustment film.

15. The method according to claim 14, wherein the contact groups include a first contact group having the greatest depth, a second contact group having the second greatest depth, and a third contact group having the smallest depth, and
wherein the adjustment film includes at least a region having a first thickness and a region having a second thickness greater than the first thickness, and
wherein contact holes in the first contact group do not extend through the adjustment film, contact holes in the second contact group extend through the adjustment film having the first thickness, and contact holes in the third contact group extend through the adjustment film having the second thickness.

16. The method according to claim 15, wherein a depth of a contact hole having the smallest depth in the first contact group is greater than a depth of a contact hole having the greatest depth in the second contact group, and a depth of a contact hole having the smallest depth in the second contact group is greater than a depth of a contact hole having the greatest depth in the third contact group.

17. The method according to claim 14, wherein the adjustment film includes, in a direction orthogonal to the semiconductor substrate, at least a first region having a first number of overlapping portions and a second region having a second number greater than the first number of overlapping portions.

18. The method according to claim 17, wherein the contact groups include a first contact group having the greatest depth, a second contact group having the second greatest depth, and a third contact group having the smallest depth, and
wherein contact holes in the first contact group do not extend through the adjustment film, contact holes in the second contact group extend through the first region of the adjustment film, and contact holes in the third contact group extend through the second region of the adjustment film.

19. The method according to claim 18, wherein a depth of a contact hole having the smallest depth in the first contact group is greater than a depth of a contact hole having the greatest depth in the second contact group, and a depth of a contact hole having the smallest depth in the second contact group is greater than a depth of a contact hole having the greatest depth in the third contact group.

20. The method according to claim 14, further comprising, after the forming the stairway portion, forming a stopper film above the stairway portion.
